(19) United States
(12) Patent Application Publication
(10) Pub. No.: US 2026/0018488 A1
(43) Pub. Date: Jan. 15, 2026

(54) INTEGRATED CIRCUIT DEVICE HAVING A TWO-PHASE THERMAL MANAGEMENT DEVICE

(71) Applicant: QUALCOMM Incorporated, San Diego, CA (US)

(72) Inventors: Le GAO, San Diego, CA (US); Youmin YU, Escondido, CA (US); Nader NIKFAR, San Diego, CA (US)

(21) Appl. No.: 18/922,657

(22) Filed: Oct. 22, 2024

Related U.S. Application Data
(63) Continuation-in-part of application No. 18/767,029, filed on Jul. 9, 2024.

(51) Int. Cl. H01L 23/427; H01L 21/48; H01L 21/56; H01L 23/00; H01L 23/053; H01L 23/31; H01L 23/373; H01L 25/065; H05K 1/18

(52) U.S. Cl. CPC H01L 23/427; H01L 21/4817; H01L 21/565; H01L 23/053; H01L 23/3128; H01L 23/3736; H01L 24/32; H01L 25/0655; H01L 2224/32225; H01L 2224/32245; H01L 2924/1815; H05K 1/181

(57) ABSTRACT

Various aspects of the present disclosure generally relate to an integrated circuit device, such as a packaged integrated circuit device. In some aspects, an integrated circuit device includes a semiconductor die and a lid thermally coupled to the semiconductor die. The lid includes a two-phase thermal management device. The integrated circuit device also includes an interface layer in contact with the semiconductor die and the lid.

### CROSS-REFERENCE TO RELATED APPLICATIONS

The present application claims priority from and is a continuation-in-part of U.S. patent application Ser. No. 18/767,029 (Atty. Dkt. No. 2402993), filed Jul. 9, 2024, and entitled “MOLD COMPOUND EMBEDDED DEVICE COOLING STRUCTURE,” the content of which is incorporated herein by reference in its entirety.

### FIELD

Various features relate to thermal management in integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. With technological advancements, such as generative artificial intelligence, that process a large amount of data in a short time, the amount of heat generated by mobile device components is increasing. These devices are susceptible to uneven heating and overheating with one or more heat sources arranged within a small form factor.

### SUMMARY

Various features relate to integrated circuit devices.

One example provides a packaged integrated circuit device that includes a semiconductor die and a lid thermally coupled to the semiconductor die. The lid includes a two-phase thermal management device. The packaged integrated circuit device also includes an interface layer in contact with the semiconductor die and the lid.

Another example provides a device that includes a packaged integrated circuit device. The packaged integrated circuit device includes a semiconductor die and a lid thermally coupled to the semiconductor die. The lid includes a two-phase thermal management device. The packaged integrated circuit device also includes an interface layer in contact with the semiconductor die and the lid.

Another example provides a method of fabricating a packaged integrated circuit device. The method includes thermally coupling a lid including a two-phase thermal management device to a semiconductor die via an interface layer positioned between the semiconductor die and the two-phase thermal management device. The method also includes coupling the lid to a package substrate, wherein the semiconductor die is coupled to the package substrate.

Another example provides a packaged integrated circuit device that includes a semiconductor die. The packaged integrated circuit device also includes a sealed two-phase thermal management device thermally coupled to the semiconductor die. The packaged integrated circuit device further includes a mold compound encapsulating the semiconductor die and the sealed two-phase thermal management device.

Another example provides a device that includes a packaged integrated circuit device and a printed circuit board (PCB) electrically connected to the packaged integrated circuit device. The packaged integrated circuit device includes a semiconductor die. The packaged integrated circuit device also includes a sealed two-phase thermal management device thermally coupled to the semiconductor die. The packaged integrated circuit device further includes a mold compound encapsulating the semiconductor die and the sealed two-phase thermal management device.

Another example provides a method of fabricating a packaged integrated circuit device, the method includes thermally coupling a sealed two-phase thermal management device to a semiconductor die. The method also includes using a mold compound to encapsulate the sealed two-phase thermal management device and the semiconductor die.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross-sectional profile view of an exemplary device that includes a mold compound embedded two-phase thermal management device.

FIG. 2 illustrates a cross-sectional profile view of an exemplary device that includes a mold compound embedded two-phase thermal management device.

FIG. 3A illustrates a cross-sectional profile view of the two-phase thermal management device of any of the devices of FIG. 1, 2, or 15-18.

FIG. 3B illustrates an example of a vapor chamber as the two-phase thermal management device of any of the devices of FIG. 1, 2, or 15-18.

FIG. 3C illustrates an example of heat pipes as the two-phase thermal management device of any of the devices of FIG. 1, 2, or 15-18.

FIG. 3D illustrates an example of a cross-section profile view of a heat pipe cooling system as a two-phase thermal management device.

FIG. 3E illustrates an example of a cross-section profile view of a loop heat pipe cooling system as a two-phase thermal management device.

FIG. 3F illustrates an example of a cross-sectional profile view of an exemplary device that includes a two-phase thermal management device.

FIG. 3G illustrates an example of a cross-sectional view of the two-phase thermal management device of FIG. 3F.

FIG. 3H illustrates another example of a cross-sectional view of the two-phase thermal management device of FIG. 3F.

FIG. 4 illustrates a mobile device that may integrate a device having a two-phase thermal management device.

FIG. 5A illustrates a cross-sectional profile view of an exemplary device that includes a mold compound embedded two-phase thermal management device thermally coupled to multiple dies.

FIG. 5B illustrates a cross-sectional profile view of an exemplary device that includes a mold compound embedded two-phase thermal management device thermally coupled to multiple dies.

FIG. 6A illustrates a cross-sectional profile view of an exemplary device that includes multiple mold compound embedded two-phase thermal management device thermally coupled to a single die.

FIG. 6B illustrates a cross-sectional profile view of an exemplary device that includes multiple mold compound embedded two-phase thermal management devices thermally coupled to a single die.

FIG. 7A illustrates a cross-sectional profile view of an exemplary device that includes multiple mold compound embedded two-phase thermal management devices thermally coupled to multiple dies.

FIG. 7B illustrates a cross-sectional profile view of an exemplary device that includes multiple mold compound embedded two-phase thermal management devices thermally coupled to multiple dies.

FIG. 8 illustrates an exemplary sequence for fabricating an exemplary device that includes a mold compound embedded two-phase thermal management device.

FIG. 9 illustrates an exemplary sequence for fabricating an exemplary device that includes a mold compound embedded two-phase thermal management device.

FIG. 10 illustrates an exemplary sequence for fabricating an exemplary device that includes a two-phase thermal management device.

FIG. 11 illustrates exemplary devices that include a mold compound embedded two-phase thermal management device.

FIG. 12 illustrates an exemplary flow diagram of a method of fabrication for a device that includes a mold compound embedded two-phase thermal management device.

FIG. 13 illustrates an exemplary flow diagram of a method of fabrication for a device that includes a two-phase thermal management device.

FIG. 14 illustrates an exemplary flow diagram of a method of fabrication for a device that includes a two-phase thermal management device.

FIG. 15 illustrates a cross-sectional profile view of an exemplary device that includes a two-phase thermal management device.

FIG. 16 illustrates a cross-sectional profile view of an exemplary device that includes a two-phase thermal management device.

FIG. 17 illustrates a cross-sectional profile view of an exemplary device that includes a two-phase thermal management device.

FIG. 18 illustrates a cross-sectional profile view of an exemplary device that includes a mold compound embedded two-phase thermal management device.

FIGS. 19A-19D illustrate cross-sectional profile views of examples of devices that include one or more two-phase thermal management devices.

FIGS. 20A-20D illustrate cross-sectional profile views of examples of devices that include one or more two-phase thermal management devices.

FIGS. 21A-21D illustrate cross-sectional profile views of examples of devices that include one or more two-phase thermal management devices.

FIGS. 22A-22D illustrate cross-sectional profile views of examples of devices that include one or more two-phase thermal management devices.

FIG. 23 illustrates an exemplary sequence for fabricating an exemplary device that includes a two-phase thermal management device.

FIG. 24 illustrates an exemplary sequence for fabricating an exemplary device that includes a two-phase thermal management device.

FIG. 25 illustrates an exemplary sequence for fabricating an exemplary device that includes a two-phase thermal management device.

FIG. 26 illustrates an exemplary sequence for fabricating an exemplary device that includes a two-phase thermal management device.

FIG. 27 illustrates various electronic devices that may integrate an exemplary mold compound embedded two-phase thermal management device described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

State-of-the-art mobile application devices demand a small form factor, low cost, a tight power budget, and high electrical performance. Mobile package design has evolved to meet these divergent goals for enabling mobile applications that support multimedia enhancements. For example, a mobile application device can include multiple antenna modules and a system-on-chip (SoC) that includes one or more processors. These mobile application devices, however, are susceptible to overheating issues when multiple heat sources (e.g., the antenna modules and SoC) are arranged within the small form factor.

Aspects of the present disclosure are directed to an IC device having a thermal management device (e.g., a two-phase thermal management device), such as a packaged IC device having a lid that includes the thermal management device. A packaged integrated circuit device includes a semiconductor die and a lid thermally coupled to the semiconductor die. The lid includes a two-phase thermal management device. The packaged integrated circuit device also includes an interface layer in contact with the semiconductor die and the lid. The disclosed packaged integrated circuit device with the lid that includes the two-phase thermal management device provides improved thermal distribution, improved resistance to warpage, or a combination thereof.

Some additional aspects of the present disclosure are directed to a mold compound embedded thermal management device. A packaged integrated circuit device includes a semiconductor die and a sealed two-phase thermal management device thermally coupled to the semiconductor die. The packaged integrated circuit device also includes a mold compound encapsulating the semiconductor die and the sealed two-phase thermal management device. The disclosed packaged integrated circuit device with the mold compound embedded thermal management device provides improved thermal distribution.

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 5A, multiple dies are illustrated and associated with reference numbers 108A and 108B. When referring to a particular one of these dies, such as a die 108A, the distinguishing letter “A” is used. However, when referring to any arbitrary one of these dies or to these dies as a group, the reference number 108 is used without a distinguishing letter.

### Exemplary Implementations of Packaged Devices Including Two-Phase Thermal Management Devices

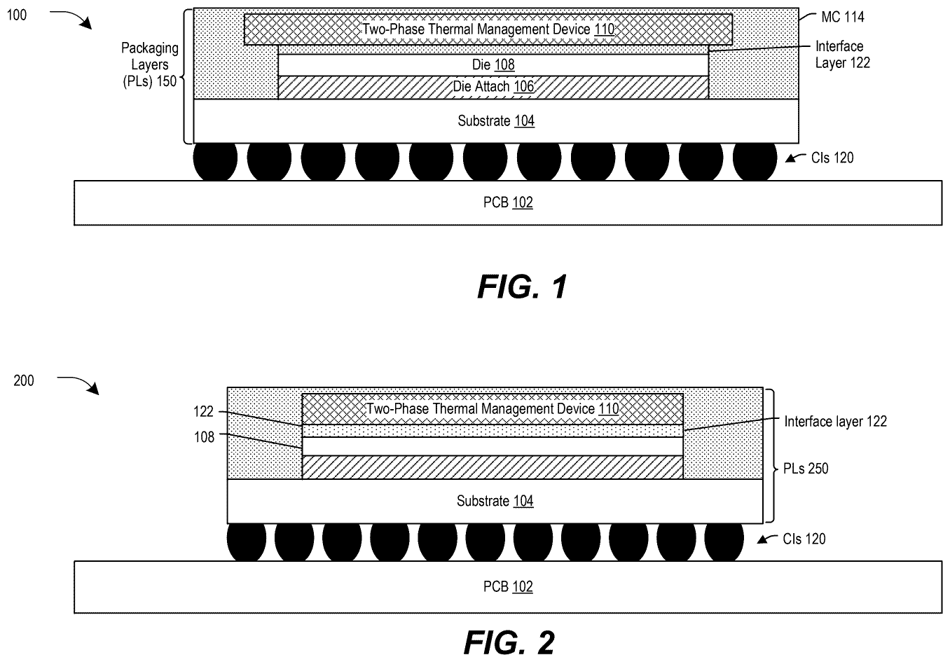

FIG. 1 illustrates a cross-sectional profile view of an exemplary device 100 that includes a mold compound embedded two-phase thermal management device. In the implementation shown in FIG. 1, the device 100 includes packaging layers (PLs) 150 electrically connected via conductive interconnects (CIs) 120 to a printed circuit board (PCB) 102.

The packaging layers 150 include a die 108 (e.g., a semiconductor die) electrically connected via a die attach 106 to a first surface (e.g., a top surface) of a substrate 104. The CIs 120 are electrically connected to a second surface (e.g., a bottom surface) of the substrate 104 that is opposite to the first surface. In a particular aspect, the die 108 includes one or more processors, a system-on-chip (SoC) including one or more processors, a central processing unit (CPU), a graphics processing unit (GPU), an audio processor, a video processor, a display, or a combination thereof. The substrate 104 is attached (e.g., via the CIs 120) to the PCB 102.

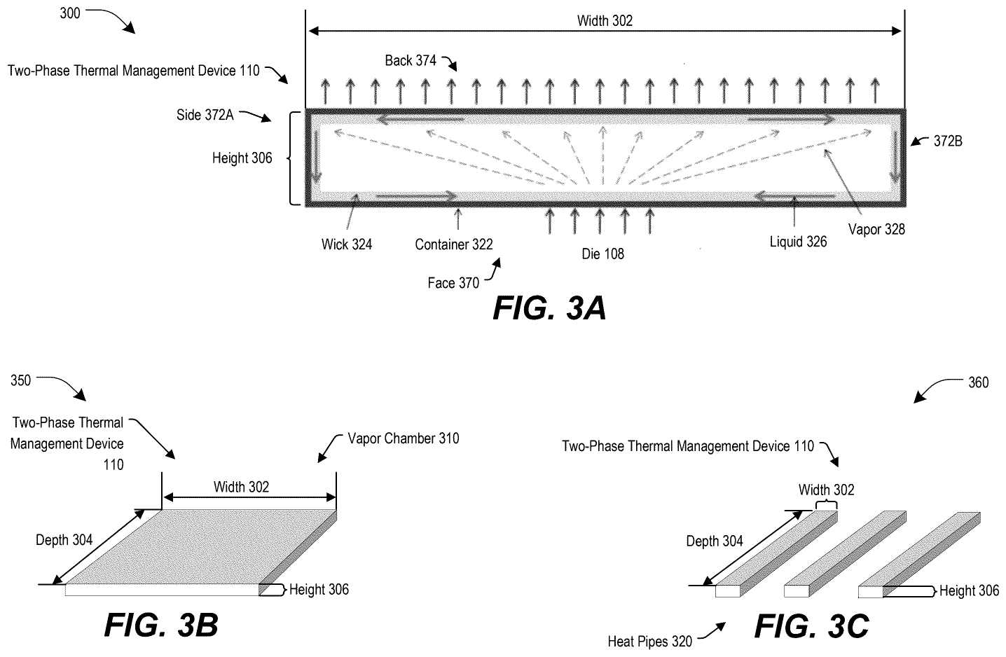

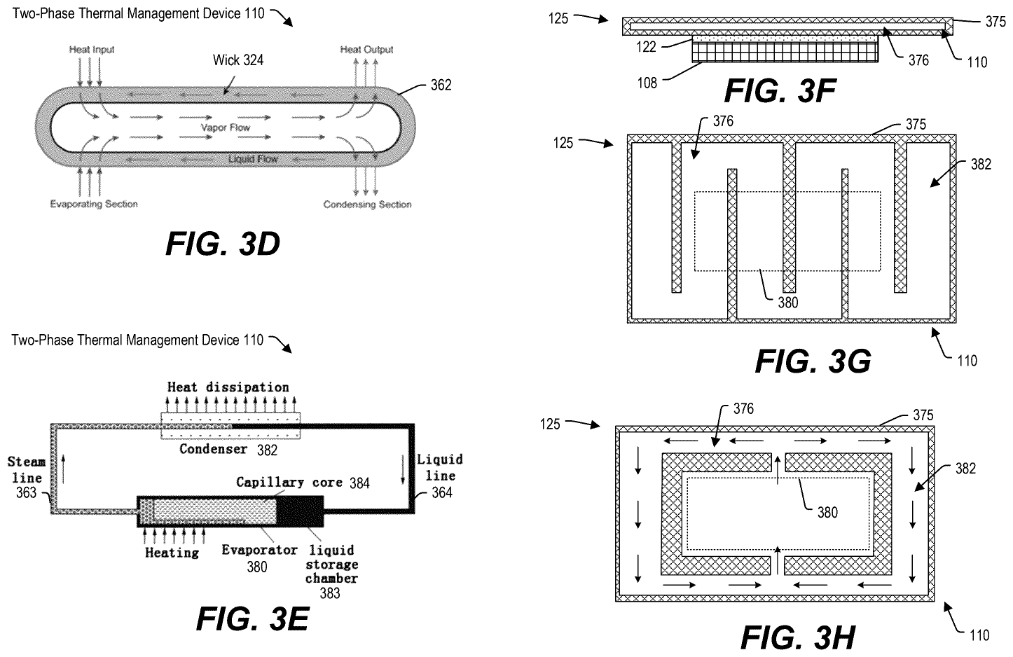

The packaging layers 150 include a mold compound (MC) 114 formed on the substrate 104. The die 108 and the die attach 106 are at least partially encapsulated in the mold compound 114. A two-phase thermal management device 110 (e.g., a two-phase cooling structure) is encapsulated (e.g., embedded) in the mold compound 114. In a particular aspect, the two-phase thermal management device 110 includes a sealed two-phase thermal management device, as further described with reference to FIG. 3. For example, the two-phase thermal management device 110 includes a vapor chamber, one or more heat pipes, a thermosyphon, or a combination thereof. The two-phase thermal management device 110 is thermally coupled to the die 108. In a particular aspect, the die 108 is between the two-phase thermal management device 110 and the substrate 104.

A first surface (e.g., a face) of the two-phase thermal management device 110 is adjacent to and aligned with a second surface (e.g., a face) of the die 108. The first surface has a first surface area and the second surface has a second surface area. In some implementations, the first surface area is larger than (e.g., greater than) the second surface area. In the example illustrated in FIG. 1, the two-phase thermal management device 110 extends (e.g., horizontally in the view shown in FIG. 1) past the edges of the die 108.

In some examples, the two-phase thermal management device 110 extends (e.g., horizontally in the view shown in FIG. 1) past one or more edges of the die 108. The first surface area may be less than, equal to, or greater than the second surface area. In yet other examples, the two-phase thermal management device does not extend (e.g., horizontally in the view shown in FIG. 2) past any edges of the die 108. To illustrate, the first surface area is less than or equal to the second surface area.

The packaging layers 150 include an interface layer 122 (e.g., a thermal interface layer) between the two-phase thermal management device 110 and the die 108. In the example of FIG. 1, the interface layer 122 includes a layer of the mold compound 114. In another example, the interface layer 122 includes another type of thermal interface layer, such as an adhesive layer (e.g., an epoxy), as further described with reference to FIG. 2. In a particular aspect, the interface layer 122 includes silicone, graphite, aluminum, boron nitride, aluminum oxide, acrylic, indium alloy, silver, copper, zinc oxide, silicon carbide, graphite, graphene, carbon nanotubes, polyurethane, metal, ceramic, polymer, elastomer, epoxy, adhesive, thermal interface material, a mold compound layer, or a combination thereof. In a particular aspect, the packaging layers 150 are enclosed in a shielding can. For example, the shielding can isolates the die 108 by creating a Faraday cage directly on the PCB 102.

In a particular implementation, the die 108 includes silicon, silicon carbide, gallium arsenide, or a combination thereof. In a particular aspect, the die attach 106 includes gold-tin, gold-silicon, a silver-filled glass compound, a silver-filled epoxy resin, or a combination thereof. In a particular aspect, the die attach 106 includes microbumps. In a particular implementation, one or more of the CIs 120 include tin, silver, copper, or a combination thereof. In a particular aspect, the mold compound 114 includes epoxy, plastic, polymer, silica, glass, or a combination thereof.

It should be understood that the device 100 may include additional components, other components, fewer components, or a combination thereof, to support the functionality described herein. As non-limiting examples, the device 100 may include additional IC devices, additional layers, additional dies, additional two-phase thermal management devices (e.g., two-phase cooling structures), additional packages, additional interconnects, additional structures, other components, different components, or a combination thereof, to support the functionality and technical advantages disclosed herein.

During operation of the device 100, when the die 108 produces heat, working fluid in an evaporator portion of the two-phase thermal management device 110 that is closer to the die 108 undergoes a phase change from liquid to vapor. As the working fluid (as vapor) spreads away from the die 108 and enters a condenser portion of the two-phase thermal management device 110, the working fluid condenses back to a liquid and flows back to the evaporator portion of the two-phase thermal management device 110. In some examples, a heat sink or condenser above (in the view shown in FIG. 3A) the condenser portion of the two-phase thermal management device 110 cools the condenser portion to cause the working fluid to condense back to a liquid.

The die 108 can include integrated circuitry, such as a plurality of transistors and/or other circuit elements arranged and interconnected to form logic cells, memory cells, etc. Components of the integrated circuitry can be formed in and/or over a semiconductor substrate (e.g., the substrate 104). Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

The die 108 may include or correspond to particular IC devices that can be arranged and interconnected as a three-dimensional (3D) IC device. In some implementations, the die 108 includes one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the die 108. Additionally, or alternatively, the dies 108 may include or operate as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

In some implementations, IC dies are electrically connected to, or integrated with, respective substrates. For example, the die 108 may be electrically connected (e.g., via one or more contacts or interconnects) to the substrate 104. In some implementations, the packaging layers 150, including the die 108, are electrically connected via the CIs 120 to the PCB 102. Any of the conductive interconnects and contacts described herein can include, for example, microbumps, conductive pillars, conductive pads (e.g., for pad-to-pad bonding), or other similar chiplet-to-chiplet interconnect contacts used for three-dimensional (3D) chiplet stacking.

The device 100 thus experiences improved thermal distribution as compared to other devices that do not include the two-phase thermal management device 110 embedded within the mold compound 114. A technical advantage of the two-phase thermal management device 110 embedded in the mold compound 114 includes improved performance of the die 108, improved heat dissipation of the device 100, or both.

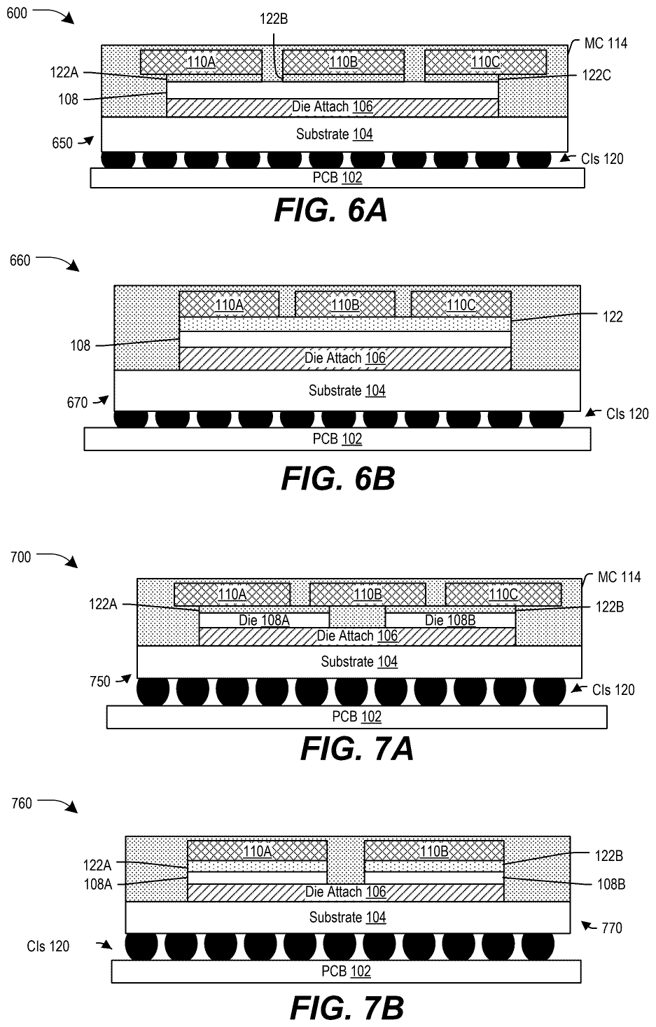

In a particular implementation, the device 100 includes multiple dies 108 encapsulated in the mold compound 114 and a single two-phase thermal management device (e.g., the two-phase thermal management device 110) is thermally coupled to the multiple dies 108, as further described with reference to FIGS. 5A and 5B. In a particular implementation, the device 100 includes multiple two-phase thermal management devices 110 encapsulated in the mold compound 114 and the multiple two-phase thermal management devices 110 are thermally coupled to a single die (e.g., the die 108), as further described with reference to FIGS. 6A and 6B. In some examples, at least one of the multiple two-phase thermal management devices 110 includes a vapor chamber and at least one of the multiple two-phase thermal management devices 110 includes one or more heat pipes.

In a particular implementation, the device 100 includes multiple dies 108 and multiple two-phase thermal management devices 110 encapsulated in the mold compound 114, as further described with reference to FIGS. 7A and 7B. In this implementation, a first die 108 is thermally coupled to a first two-phase thermal management device 110 and a second die 108 is thermally coupled to a second two-phase thermal management device 110. In some examples, the first two-phase thermal management device 110 includes a vapor chamber and the second two-phase thermal management device 110 includes one or more heat pipes.

FIG. 2 illustrates a cross-sectional profile view of a particular implementation of a device 200 that includes a mold compound embedded device two-phase thermal management device (e.g., the two-phase thermal management device 110). The device 200 of FIG. 2 includes many of the same components and features as are described above with reference to FIG. 1. Such components and features are physically and operationally the same as described above with reference to FIG. 1 and are labeled in FIG. 2 using the same reference numbers.

In the example shown in FIG. 2, the device 200 includes PLs 250 attached via the CIs 120 to the PCB 102. The PLs 250 include the interface layer 122 (e.g., a thermal interface layer, such as an epoxy) between the two-phase thermal management device 110 and the die 108.

A first surface (e.g., a face) of the two-phase thermal management device 110 is adjacent to and aligned with a second surface (e.g., a face) of the die 108. The first surface has a first surface area, and the second surface has a second surface area. In the example illustrated in FIG. 2, the first surface area is at least as large as the second surface area. In some other examples, the first surface area can be less than the second surface area.

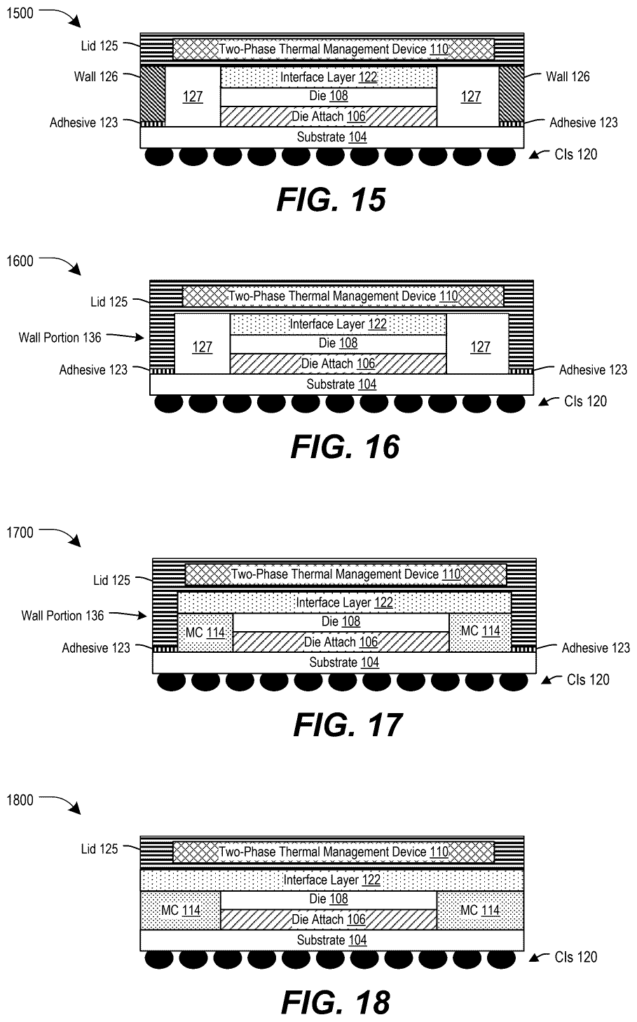

FIG. 15 illustrates a cross-sectional profile view of an exemplary device 1500 that includes a two-phase thermal management device (e.g., the two-phase thermal management device 110). In the implementation shown in FIG. 15, the device 1500 includes an integrated circuit (IC) device, such as a packaged IC device, which is configured to be electrically connected to a PCB (e.g., the PCB 102) via CIs 120. The device 1500 of FIG. 15 includes many of the same components and features as are described above with reference to FIG. 1. Such components and features may be physically and operationally the same as described above with reference to FIG. 1 and are labeled in FIG. 15 using the same reference numbers.

The device 1500 includes a substrate 104, a die attach 106, a die 108 (e.g., a semiconductor die), an interface layer 122, a lid 125, and one or more walls 126 (hereinafter referred to collectively as “the wall 126”). The substrate 104 is configured to be coupled to the die 108, the CIs 120, or a combination thereof. For example, substrate 104 may include a first surface (e.g., a top surface) that is configured to be electrically coupled to the die, and a second surface (e.g., a bottom surface) that is configured to be electrically coupled to the CIs 120. Additionally, the substrate 104 can be configured to be attached (e.g., via the CIs 120) to a PCB, such as the PCB 102. For example, the substrate 104 may be electrically coupled to the PCB.

The die 108 is electrically connected via the die attach 106 to the first surface (e.g., the top surface) of the substrate 104. In a particular aspect, the die 108 includes one or more processors, a SoC including one or more processors, a CPU, a GPU, an audio processor, a video processor, or a combination thereof. Additionally, or alternatively, the die 108 may include silicon, silicon carbide, gallium arsenide, or a combination thereof, as illustrative, non-limiting examples. In a particular aspect, the die attach 106 includes gold-tin, gold-silicon, a silver-filled glass compound, a silver-filled epoxy resin, or a combination thereof, as illustrative, non-limiting examples. Additionally, or alternatively, the die attach 106 may include microbumps.

The CIs 120 may be electrically connected to the second surface (e.g., a bottom surface) of the substrate 104 that is opposite to the first surface of the substrate 104. The one or more of the CIs 120 include tin, silver, copper, or a combination thereof, as illustrative, non-limiting examples.

The wall 126 is coupled to the substrate 104 via an adhesive layer 123. The adhesive layer 123 includes an adhesive material, such as an epoxy, as an illustrative, non-limiting example. The wall 126 may include a structure that includes a metal or alloy, such as copper, brass, aluminum, silver, tin, steel, or a combination thereof, as illustrative, non-limiting examples. In some implementations, the wall 126 includes a structure, such as a ring (e.g., a stiffener ring). Additionally, or alternatively, the wall 126 may include multiple walls, such as multiple concentric walls. To illustrate, as shown in FIG. 15, the wall 126 is positioned at an end portion of the substrate 104 and another wall can be positioned on the substrate 104 between the die 108 and the wall 126 positioned at the end of the substrate 104. The wall 126 may increase resistance to package warpage and/or provide structural support for the device 1500.

The lid 125 is coupled to the wall 126. For example, the lid 125 may be coupled to the wall 126 via a coupling material, such as an epoxy, as an illustrative, non-limiting example.

The lid 125 is thermally coupled to the die 108 via at least the interface layer 122. For example, the interface layer 122 is positioned between the lid 125 and the die 108. In some implementations, the interface layer 122 (e.g., a thermal interface layer) is in contact with the die 108 and the lid 125. The interface layer 122 may include silicone, graphite, aluminum, boron nitride, aluminum oxide, acrylic, indium alloy, silver, copper, zinc oxide, silicon carbide, graphite, graphene, carbon nanotubes, polyurethane, metal, ceramic, polymer, elastomer, epoxy, adhesive, thermal interface material (TIM), a mold compound layer, or a combination thereof. In a particular implementation, the interface layer includes a thermal interface layer (e.g., the TIM).

The lid 125, the wall 126, or both, define a portion of an outer surface of the device 1500 (e.g., a packaged integrated circuit device). Alternatively, in some implementations, the device 1500 may not include the wall 126. In some such implementations, the lid 125 can include a wall portion and the lid 125 can be coupled to the substrate 104 via an adhesive layer, as described further herein at least with reference to FIG. 16, or the lid 125 can be coupled to the substrate 104 via the interface layer 122, a mold compound, or a combination thereof, as described herein at least with reference to FIG. 18.

The lid 125 includes the two-phase thermal management device 110. In some implementations, the two-phase thermal management device includes a sealed two-phase thermal management device, as further described with reference to FIG. 3. For example, the two-phase thermal management device 110 includes a vapor chamber, one or more heat pipes, a thermosyphon, or a combination thereof. Additionally, or alternatively, the two-phase thermal management device may include a structure, such as a copper structure, which surrounds a cavity of the two-phase thermal management device. The two-phase thermal management device 110 is thermally coupled to the die 108. In a particular aspect, the die 108 is positioned between the lid 125 (e.g., the two-phase thermal management device 110) and the substrate 104. For example, the die 108 may be interposed between the two-phase thermal management device 110 and the substrate 104.

In some implementations, the lid 125 includes one or more layers, such as one or more metal layers. To illustrate, the one or more layers may include copper, as an illustrative, non-limiting example. The one or more layers may be coupled to and/or enclose the two-phase thermal management device 110. For example, the lid 125 may include a first layer positioned below the two-phase thermal management device 110, a second layer positioned above the two-phase thermal management device 110, or a combination thereof. Alternatively, an entirety of the lid 125 is the two-phase thermal management device 110.

In some implementations, the two-phase thermal management device 110 has a first surface (e.g., a face) that faces the die 108, and the die 108 has a second surface (e.g., a face) that faces the two-phase thermal management device. An area (e.g., a total area) of the first surface of the two-phase thermal management device 110 may be larger (greater) than or equal to an area (e.g., a total area) of the second surface of the die 108. Alternatively, the area (e.g., a total area) of the first surface of the two-phase thermal management device 110 may be less than the area (e.g., a total area) of the second surface of the die 108.

In some implementations, the first surface of the two-phase thermal management device 110 has one or more first dimensions (e.g., a length, a width, or both) in a horizontal direction (e.g., horizontally in the view shown in FIG. 15), and the second surface of the die 108 has one or more second dimensions (e.g., a length, a width, or both) in the horizontal direction. At least one dimension of the one or more first dimensions of the first surface of the two-phase thermal management device 110 may be greater than or equal to a corresponding at least one dimension of the one or more second dimension of the second surface of the die 108. For example, a length dimension of the first surface of the two-phase thermal management device 110 may be greater than or equal to a length dimension of the second surface of the die 108. Additionally, or alternatively, at least one dimension of the one or more first dimensions of the first surface of the two-phase thermal management device 110 may be less than or equal to a corresponding at least one dimension of the one or more second dimension of the second surface of the die 108. For example, a width dimension of the first surface of the two-phase thermal management device 110 may be less than or equal to a width dimension of the second surface of the die 108. In some examples, the two-phase thermal management device 110 extends (e.g., horizontally in the view shown in FIG. 15) past one or more edges of the die 108. The two-phase thermal management device extends past an edge of the semiconductor die. Additionally, or alternatively, the two-phase thermal management device may not extend (e.g., horizontally in the view shown in FIG. 2) past any edges of the die 108.

The lid 125, the wall 126, the adhesive layer 123, the substrate 104, or a combination thereof define a cavity 127. The die 108, the die attach 106, and the interface layer 122 are positioned within the cavity 127.

During operation of the device 1500, when the die 108 produces heat, working fluid in an evaporator portion of the two-phase thermal management device 110 that is closer to the die 108 undergoes a phase change from liquid to vapor. As the working fluid (as vapor) spreads away from the die 108 and enters a condenser portion of the two-phase thermal management device 110, the working fluid condenses back to a liquid and flows back to the evaporator portion of the two-phase thermal management device 110. In some examples, a heat sink or condenser above (in the view shown in FIG. 3A) the condenser portion of the two-phase thermal management device 110 cools the condenser portion to cause the working fluid to condense back to a liquid.

The device 1500 thus experiences improved thermal distribution as compared to other devices that do not include the two-phase thermal management device 110. A technical advantage of the two-phase thermal management device 110 includes improved performance of the die 108, improved heat dissipation of the device 1500, or both. Additionally, or alternatively, the lid 125, including the two-phase thermal management device 110, and/or the wall 126 provides structural support to the device. A technical advantage of the lid 125 and/or the wall 126 includes improved resistance to warpage of the device 1500 that may result from heat generated by the die 108.

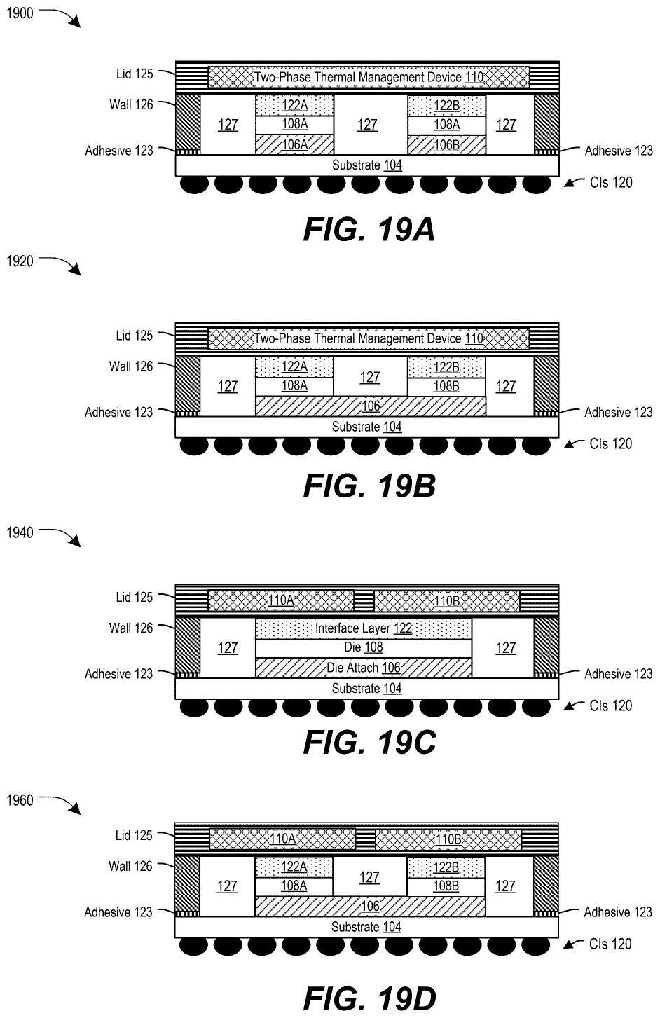

In a particular implementation, the device 1500 includes multiple dies 108, as further described with reference to FIGS. 19A, 19B, and 19D. For example, the device 1500 can include a second die (e.g., a second semiconductor die) coupled to the substrate 104, as described further herein at least with reference to FIG. 19A, 19B, or 19D. The lid 125 may be thermally coupled to the second die, and the second die is positioned between the substrate 104 and the lid 125. Additionally, or alternatively, the lid 125 can include one or more two-phase thermal management devices 110. For example, the lid 125 can include a single two-phase thermal management device (e.g., the two-phase thermal management device 110), as further described with reference to FIGS. 19A and 19B. Alternatively, the device 1500 includes multiple two-phase thermal management devices 110, such as a first two-phase thermal management device and a second two-phase thermal management device, as described further herein at least with reference to FIGS. 19C and 19D. The multiple two-phase thermal management devices 110 can be thermally coupled to one or more dies, such as a single die (e.g., the die 108), as further described with reference to FIG. 19C, or multiple dies 108, as further described with reference to FIG. 19D.

FIG. 16 illustrates a cross-sectional profile view of an exemplary device 1600 that includes a two-phase thermal management device (e.g., the two-phase thermal management device 110). In the implementation shown in FIG. 16, the device 1600 includes an IC device, such as a packaged IC device, which is configured to be electrically connected to a PCB (e.g., the PCB 102) via CIs 120. The device 1600 of FIG. 16 includes many of the same components and features as are described above with reference to FIGS. 1 and/or 15. Such components and features may be physically and operationally the same as described above with reference to FIGS. 1 and/or 15 and are labeled in FIG. 16 using the same reference numbers.

As compared to the device 1500 of FIG. 15, the device 1600 includes the lid 125 that includes one or more wall portions 136 (hereinafter referred to collectively as “the wall portions 136”). In some implementations, the lid 125 includes a base portion (that includes the two-phase thermal management device 110) and the wall portion 136 is coupled to and extends from the base portion. Additionally, it is noted that in the example of the device 1600 shown in FIG. 16, the device 1600 does not include the wall 126. The lid 125 of the device 1600 is coupled to the substrate 104 via the adhesive layer 123. To illustrate, the wall portion 136 of the lid 125 is coupled to the substrate 104 via the adhesive layer 123.

In some implementations, prior to formation of the device 1600, the lid 125 is pressed or stamped to form the wall portion 136. For example, the lid 125 may include one or more layers, such as one or more metal layers, and a pressing operation, a stamping operation, or a bending operation may be performed on the one or more layers to form the wall portion 136. Additionally, or alternatively, prior to formation of the device 1600, one or more walls may be coupled to the base portion of the lid to form the wall portions 136.

The lid 125 defines a portion of an outer surface of the device 1600 (e.g., a packaged integrated circuit device). The lid 125, the adhesive layer 123, the substrate 104, or a combination thereof define a cavity 127. The die 108, the die attach 106, and the interface layer 122 are positioned within the cavity 127.

The device 1600 having the two-phase thermal management device 110 may experience improved thermal distribution as compared to other devices that do not include the two-phase thermal management device 110. A technical advantage of the two-phase thermal management device 110 includes improved performance of the die 108, improved heat dissipation of the device 1600, or both. Additionally, or alternatively, the lid 125, including the two-phase thermal management device 110 and the wall portion 136, provides structural support to the device. A technical advantage of the lid 125 (including the two-phase thermal management device 110 and the wall portion 136) includes improved resistance to warpage of the device 1600 that may result from heat generated by the die 108.

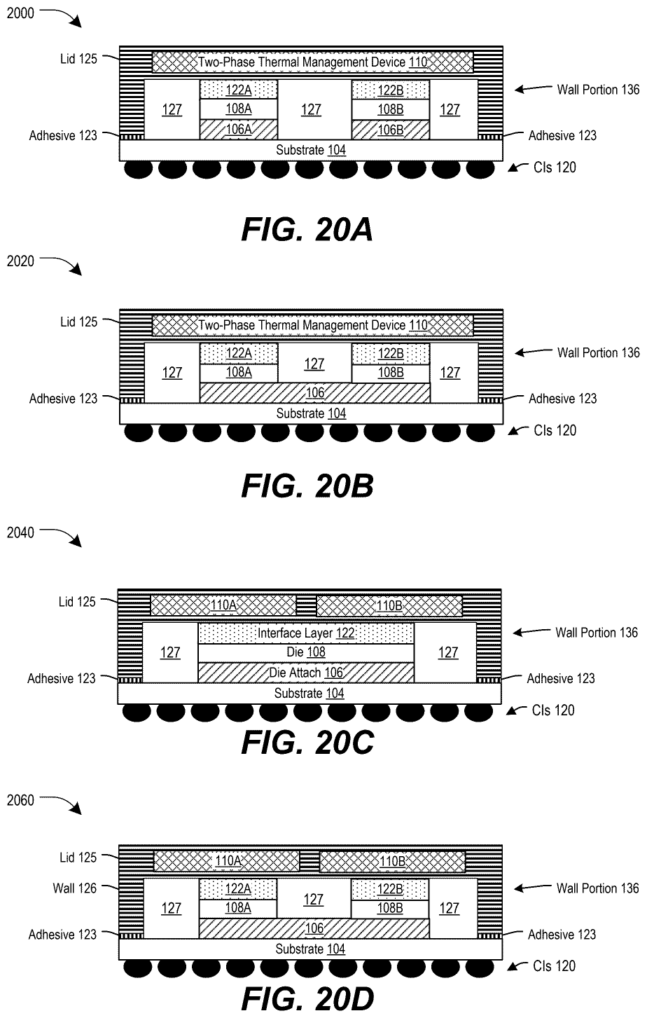

In a particular implementation, the device 1600 includes multiple dies 108, as further described with reference to FIGS. 20A, 20B, and 20D. For example, the device 1600 can include a second die (e.g., a second semiconductor die) coupled to the substrate 104, as described further herein at least with reference to FIG. 20A, 20B, or 20D. The lid 125 may be thermally coupled to the second die, and the second die is positioned between the substrate 104 and the lid 125. Additionally, or alternatively, the lid 125 can include one or more two-phase thermal management devices 110. For example, the lid 125 can include a single two-phase thermal management device (e.g., the two-phase thermal management device 110), as further described with reference to FIGS. 20A and 20B. Alternatively, the device 1600 includes multiple two-phase thermal management devices 110, such as a first two-phase thermal management device and a second two-phase thermal management device, as described further herein at least with reference to FIGS. 20C and 20D. The multiple two-phase thermal management devices 110 can be thermally coupled to one or more dies, such as a single die (e.g., the die 108), as further described with reference to FIG. 20C, or multiple dies 108, as further described with reference to FIG. 20D.

FIG. 17 illustrates a cross-sectional profile view of an exemplary device 1700 that includes a two-phase thermal management device (e.g., the two-phase thermal management device 110). In the implementation shown in FIG. 17, the device 1700 includes an IC device, such as a packaged IC device, which is configured to be electrically connected to a PCB (e.g., the PCB 102) via CIs 120. The device 1700 of FIG. 17 includes many of the same components and features as are described above with reference to FIGS. 1, 15, and/or 16. Such components and features may be physically and operationally the same as described above with reference to FIGS. 1, 15, and/or 16 and are labeled in FIG. 17 using the same reference numbers.

The device 1700 includes the lid 125. The lid 125 defines a portion of an outer surface of the device 1700 (e.g., a packaged integrated circuit device). In the example of the device 1700 shown in FIG. 17, the lid 125 includes the wall portion 136. However, in other implementations, the device 1700 may include the lid 125 that is coupled to the wall 126 as described with reference to FIG. 15.

The device 1700 includes mold compound 114. The mold compound 114 is coupled to the substrate 104, the die attach 106, the interface layer 122, the adhesive layer 123, the lid (e.g., the wall portion 136), or a combination thereof. The die 108 and the die attach 106 may be at least partially encapsulated in the mold compound 114.

The device includes the interface layer 122. For example, the interface layer 122 is positioned between the lid 125 and the die 108. Additionally, or alternatively, the interface layer 122 is positioned between the lid 125 and the mold compound 114. The interface layer 122 may be coupled to the die 108, the mold compound 114, the lid 125, or a combination thereof. For example, the interface layer 122 may be in contact with the die 108, the mold compound 114, or a combination thereof. In some implementations, the interface layer 122 may be thermally coupled to the lid 125 (e.g., the two-phase thermal management device 110) and the die 108.

In some implementations, the mold compound 114 is positioned between the die 108 and the interface layer 122. To illustrate, the mold compound 114 may be positioned between the die 108 and the interface layer 122 such that the interface layer 122 is not in contact with the die 108. Additionally, or alternatively, the mold compound 114 may be positioned between the interface layer 122 and the lid 125. To illustrate, the mold compound 114 may be positioned between the interface layer 122 and the lid 125 such that the interface layer 122 is not in contact with the lid 125.

In some implementations, the lid 125, the adhesive layer 123, the substrate 104, or a combination thereof define a cavity. The die 108, the die attach 106, the mold compound 114, and the interface layer 122 may be positioned within the cavity.

The device 1700 having the two-phase thermal management device 110 may experience improved thermal distribution as compared to other devices that do not include the two-phase thermal management device 110. A technical advantage of the two-phase thermal management device 110 includes improved performance of the die 108, improved heat dissipation of the device 1700, or both. Additionally, or alternatively, the lid 125, including the two-phase thermal management device 110 and the wall portion 136, provides structural support to the device. A technical advantage of the lid 125 (including the two-phase thermal management device 110 and the wall portion 136) includes improved resistance to warpage of the device 1700 that may result from heat generated by the die 108.

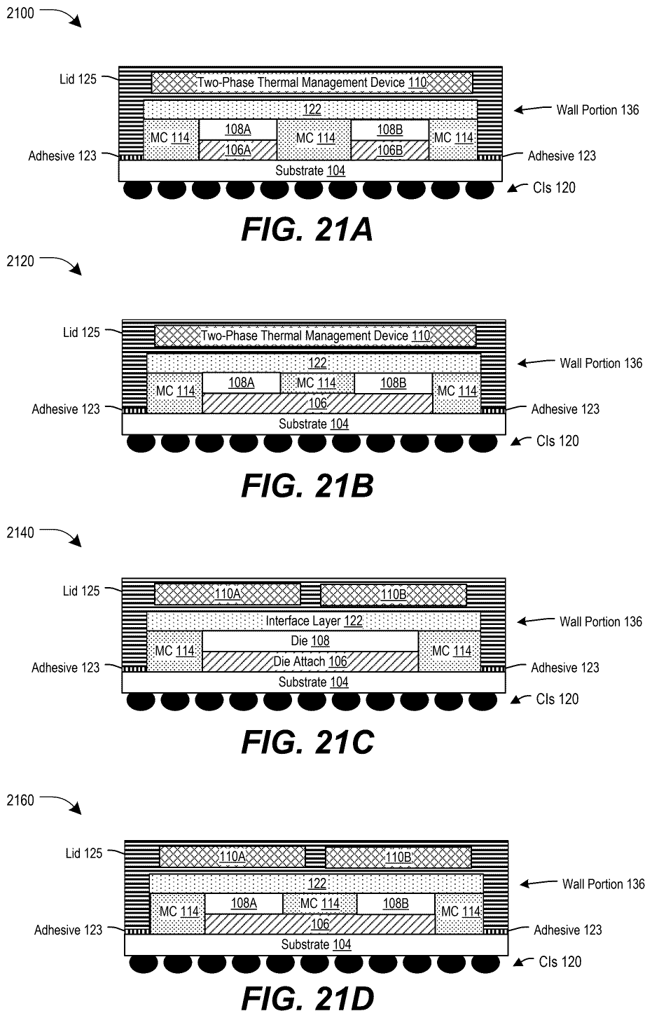

In a particular implementation, the device 1700 includes multiple dies 108, as further described with reference to FIGS. 21A, 21B, and 21D. For example, the device 1700 can include a second die (e.g., a second semiconductor die) coupled to the substrate 104, as described further herein at least with reference to FIG. 21A, 210B, or 21D. The lid 125 may be thermally coupled to the second die, and the second die is positioned between the substrate 104 and the lid 125. Additionally, or alternatively, the lid 125 can include one or more two-phase thermal management devices 110. For example, the lid 125 can include a single two-phase thermal management device (e.g., the two-phase thermal management device 110), as further described with reference to FIGS. 21A and 21B. Alternatively, the device 1700 includes multiple two-phase thermal management devices 110, such as a first two-phase thermal management device and a second two-phase thermal management device, as described further herein at least with reference to FIGS. 21C and 21D. The multiple two-phase thermal management devices 110 can be thermally coupled to one or more dies, such as a single die (e.g., the die 108), as further described with reference to FIG. 21C, or multiple dies 108, as further described with reference to FIG. 21D.

FIG. 18 illustrates a cross-sectional profile view of an exemplary device 1800 that includes a two-phase thermal management device (e.g., the two-phase thermal management device 110). In the implementation shown in FIG. 18, the device 1800 includes an IC device, such as a packaged IC device, which is configured to be electrically connected to a PCB (e.g., the PCB 102) via CIs 120. The device 1800 of FIG. 18 includes many of the same components and features as are described above with reference to FIG. 1 or 15. Such components and features may be physically and operationally the same as described above with reference to FIGS. 1 and/or 15-17 and are labeled in FIG. 18 using the same reference numbers.

The device 1800 includes the lid 125. The lid 125 defines a portion of an outer surface of the device 1800 (e.g., a packaged integrated circuit device). In the example of the device 1800 shown in FIG. 18, the lid 125 is not coupled to the wall 126 and does not include the wall portion 136.

The device 1800 includes mold compound 114. The mold compound 114 is coupled to the substrate 104, the die attach 106, the interface layer 122, or a combination thereof. In some implementations, the die 108 and the die attach 106 may be at least partially encapsulated in the mold compound 114. The mold compound 114 may define a portion of an outer surface of the device 1800 (e.g., a packaged integrated circuit device).

The device includes the interface layer 122. For example, the interface layer 122 is positioned between the lid 125 and the die 108. Additionally, or alternatively, the interface layer 122 is positioned between the lid 125 and the mold compound 114. The interface layer 122 may be coupled to the die 108, the mold compound 114, the lid 125, or a combination thereof. For example, the interface layer 122 may be in contact with the die 108, the mold compound 114, or a combination thereof. In some implementations, the interface layer 122 may be thermally coupled to the lid 125 (e.g., the two-phase thermal management device 110) and the die 108. The interface layer 122 may define a portion of an outer surface of the device 1800 (e.g., a packaged integrated circuit device).

In some implementations, the mold compound 114 is positioned between the die 108 and the interface layer 122. To illustrate, the mold compound 114 may be positioned between the die 108 and the interface layer 122 such that the interface layer 122 is not in contact with the die 108. Additionally, or alternatively, the mold compound 114 may be positioned between the interface layer 122 and the lid 125. To illustrate, the mold compound 114 may be positioned between the interface layer 122 and the lid 125 such that the interface layer 122 is not in contact with the lid 125.

The device 1800 having the two-phase thermal management device 110 may experience improved thermal distribution as compared to other devices that do not include the two-phase thermal management device 110. A technical advantage of the two-phase thermal management device 110 includes improved performance of the die 108, improved heat dissipation of the device 1800, or both. Additionally, or alternatively, the lid 125, including the two-phase thermal management device 110, provides structural support to the device 1800. A technical advantage of the lid 125 (including the two-phase thermal management device 110) includes improved resistance to warpage of the device 1800 that may result from heat generated by the die 108.

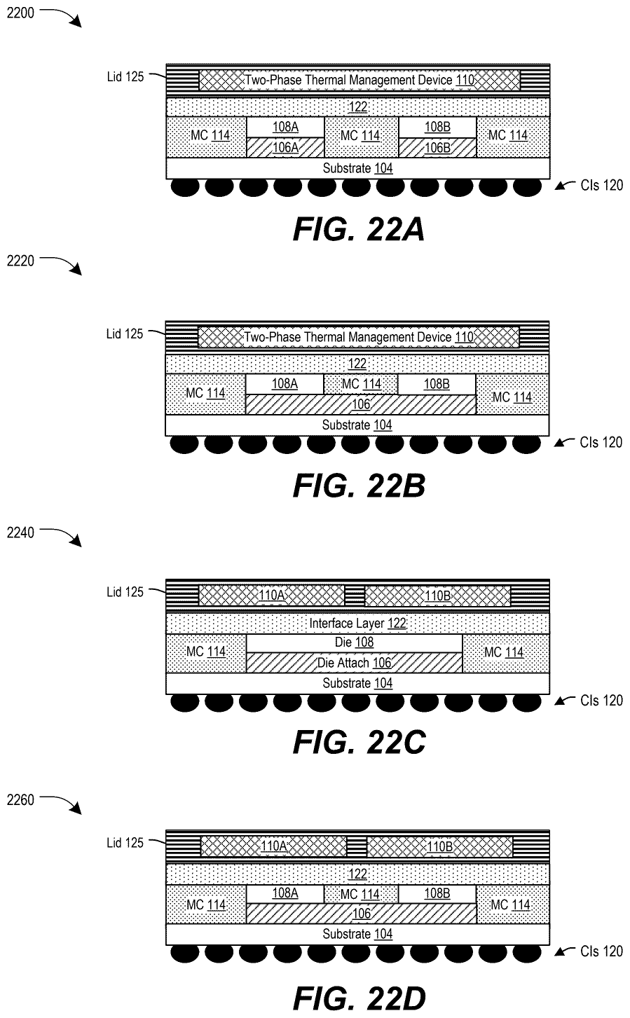

In a particular implementation, the device 1800 includes multiple dies 108, as further described with reference to FIGS. 22A, 22B, and 22D. For example, the device 1800 can include a second die (e.g., a second semiconductor die) coupled to the substrate 104, as described further herein at least with reference to FIG. 22A, 22B, or 22D. The lid 125 may be thermally coupled to the second die, and the second die is positioned between the substrate 104 and the lid 125. Additionally, or alternatively, the lid 125 can include one or more two-phase thermal management devices 110. For example, the lid 125 can include a single two-phase thermal management device (e.g., the two-phase thermal management device 110), as further described with reference to FIGS. 22A and 22B. Alternatively, the device 1800 includes multiple two-phase thermal management devices 110, such as a first two-phase thermal management device and a second two-phase thermal management device, as described further herein at least with reference to FIGS. 22C and 22D. The multiple two-phase thermal management devices 110 can be thermally coupled to one or more dies, such as a single die (e.g., the die 108), as further described with reference to FIG. 22C, or multiple dies 108, as further described with reference to FIG. 22D.

It should be understood that one or more of the devices of FIGS. 15-18 may include additional components, other components, fewer components, or a combination thereof, to support the functionality described herein. As non-limiting examples, one or more of the devices of FIGS. 15-18 may include additional IC devices, additional layers, additional dies, additional two-phase thermal management devices, additional packages, additional interconnects, additional structures, other components, different components, or a combination thereof, to support the functionality and technical advantages disclosed herein.

In some implementations, one or more of the devices of FIG. 15 or 16 may include mold compound, such as the mold compound 114. The mold compound 114 may be positioned within the cavity 127 along with the semiconductor die, a die attach, and an interface layer. Additionally, or alternatively, the mold compound may be coupled to the substrate 104, a side surface of the die 108, a side surface of the die attach 106 positioned between the substrate 104 and the die 108, or a combination thereof. In some such implementations, the mold compound at least partially encapsulates the die attach 106 and/or the die 108. In some embodiments, the mold compound is interposed between the interface layer 122 and the substrate 104. Additionally, or alternatively, the interface layer 122 may be interposed between the mold compound and the lid 125.

In some implementations, one or more of the devices of FIG. 15 or 16 may include one or more walls, such as the wall 126. For example, a wall may be positioned in the cavity 127 and coupled to the substrate 104, the lid 125, or a combination thereof. To illustrate, the wall may be coupled to the substrate 104 or the lid 125 as described with reference to the wall 126 of FIG. 15. The wall may increase resistance to package warpage and/or provide structural support for one or more of the devices of FIG. 15 or 16. With reference to FIG. 15, the device 1500 may include multiple walls 126. With reference to FIG. 16, the device 1600 may include one or more walls 126 in addition to the wall portion 136 of the lid 125 of FIG. 16.

In some implementations, the device of FIG. 15 that includes the lid 125 and the wall 126 or one or more devices of FIG. 16 or 17 that include the lid 125 having the wall portion 136 may be configured and/or coupled to form a shielding can to isolate the die 108 by creating a Faraday cage directly on the substrate 104. In other implementations, one or more of the devices of FIGS. 15-18 may be coupled to a PCB and the device is enclosed in a shielding can. For example, the shielding can may isolate the die 108 by creating a Faraday cage directly on the PCB.

In some implementations, one or more of the devices of FIGS. 15-18 may not include the CIs 120. Although each of the devices of FIGS. 15-18 is shown as including the CIs 120, in other implementations, one or more of the devices of FIGS. 15-18 may not have or include the CIs 120.

FIG. 3A illustrates a cross-sectional profile view of a particular implementation of the two-phase thermal management device 110 of the device 100 of FIG. 1, the device 200 of FIG. 2, or a device of one of FIGS. 15-18. FIG. 3B illustrates an example 350 of a particular implementation of the two-phase thermal management device 110 as a vapor chamber 310. FIG. 3C illustrates an example 360 of a particular implementation of the two-phase thermal management device 110 as one or more heat pipes 320. In some implementations, the device 100 of FIG. 1, the device 200 of FIG. 2, or both, include multiple heat pipes 320 as the two-phase thermal management device 110. FIG. 3D illustrates an example of a cross-section profile view of a heat pipe cooling system as the two-phase thermal management device 110. FIG. 3E illustrates an example of a cross-section profile view of a loop heat pipe cooling diagram as the two-phase thermal management device 110. FIG. 3F illustrates an example of a cross-sectional profile view of an exemplary device that includes the two-phase thermal management device 110. FIGS. 3G and 3H illustrate examples of a cross-sectional view of the two-phase thermal management device 110 of FIG. 3F.

In a particular aspect, the two-phase thermal management device 110 corresponds to a rectangular container 322. For example, the two-phase thermal management device 110 has a face 370, a back 374, and two sides 372 (e.g., a side 372A and a side 372B) defining a space therebetween. The face 370 is opposite to the back 374 and the side 372A is opposite to the side 372B. In a particular aspect, a surface area of the face 370 is greater than a surface area of each of the sides 372 and is the same as a surface area of the back 374. In a particular aspect, each of the sides 372 has a height 306 and each of the faces 370 and the back 374 has a width 302. The vapor chamber 310 has a depth 304. In a particular aspect, the height 306 is less than each of the width 302 and the depth 304. In a particular aspect, the two-phase thermal management device 110 corresponds to a hollow tube, such as a heat pipe 320, or a hollow chamber, such as a vapor chamber 310. In a particular aspect, the container 322 is sealed.

In a particular aspect, the two-phase thermal management device 110 is made of conductive materials (e.g., copper, aluminum, or both). According to some implementations, a wicking structure 324 is formed on the inside of the container 322. According to some implementations, a grain size of the wicking structure 324 is greater than or equal to 8 microns and less than or equal to 12 microns. In a particular example, a characteristic grain size of the wicking structure is approximately equal to 10 microns.

A working fluid is added in a volume defined by the two-phase thermal management device 110. In some implementations, the working fluid includes water, distilled water, acetone, one or more additives, or a combination thereof. The working fluid has greater than threshold thermal conductivity (e.g., greater than or equal to 0.6 watts per meter-kelvin at room temperature (25 degrees Celsius)) and lower than threshold boiling point (e.g., less than or equal to 100 degrees Celsius). In some implementations, an operating pressure of the two-phase thermal management device 110 may be set to achieve a lower boiling point (e.g., less than or equal to room temperature).

In an example, the two-phase thermal management device 110 is in thermal communication with a heat source (e.g., one or more dies 108) coupled to (e.g., proximate to) the two-phase thermal management device 110. In a particular aspect, the heat source (e.g., one or more dies 108) includes one or more processors, a SoC including one or more processors, a CPU, a GPU, an audio processor, a video processor, a display, or a combination thereof. When the heat source (e.g., a die 108) produces heat, the inside of the two-phase thermal management device 110 warms up and the working fluid undergoes a phase change from liquid 326 to vapor 328 at a relatively low temperature. According to some implementations, the two-phase thermal management device 110 includes one or more evaporator portions where heat from the heat source (e.g., the die 108) is applied to the working fluid and the working fluid undergoes the phase change from liquid 326 to vapor 328.

As the working fluid (e.g., as vapor 328) spreads away from the heat source, the working fluid passes from the one or more evaporator portions to one or more cooler condenser portions of the two-phase thermal management device 110 and condenses to a liquid phase. According to some implementations, the two-phase thermal management device 110 is in thermal communication with one or more heatsinks. The one or more heatsinks include an ambient environment, a heat spreader, or both. A region (e.g., the condenser portions) of the two-phase thermal management device 110, cooled by a heatsink, causes the working fluid in the region to condense. The working fluid (e.g., as liquid 326) flows back via the wicking structure 324 (e.g., via capillary action) to the one or more evaporator portions of the two-phase thermal management device 110. In a particular aspect, the one or more evaporator portions are closer to the back 374, and the one or more condenser portions are closer to the face 370 of the two-phase thermal management device 110.

FIG. 3D illustrates an example of a cross-section profile view of a heat pipe cooling system as a two-phase thermal management device 110. The heat pipe cooling system includes a heat pipe 362 that includes (e.g., houses) a working fluid in a liquid state and/or vapor state. The heat pipe 362 may be made of a conductive material, such as copper, aluminum, or a combination thereof, as illustrative, non-limiting examples.

The two-phase thermal management device 110 is in thermal communication with a heat source (e.g., one or more dies 108) coupled to (e.g., proximate to) the two-phase thermal management device 110. When the heat source (e.g., a die 108) produces heat, the inside the two-phase thermal management device 110 warms up and the working fluid undergoes a phase change from liquid to vapor. For example, the heat pipe 362 may receive a heat input based on the heat from the heat source. According to some implementations, the two-phase thermal management device 110 includes one or more evaporator portions/sections where heat from the heat source (e.g., the die 108) is applied to the working fluid and the working fluid undergoes the phase change from liquid to vapor.

As the working fluid (e.g., as vapor) spreads away from the heat source, the working fluid passes from the one or more evaporator portions to one or more cooler condenser portions/sections of the two-phase thermal management device 110 and condenses to a liquid phase—e.g., heat is output by the heating pipe 362. According to some implementations, the two-phase thermal management device 110 is in thermal communication with one or more heatsinks. The one or more heatsinks include an ambient environment, a heat spreader, or both. A region (e.g., the condenser portions) of the two-phase thermal management device 110, cooled by a heatsink, causes the working fluid in the region to condense. The working fluid (e.g., as liquid) flows back via the wicking structure 324 (e.g., via capillary action) to the one or more evaporator portions of the two-phase thermal management device 110.

FIG. 3E illustrates an example of a cross-section profile view of a loop heat pipe cooling system as the two-phase thermal management device 110. In some implementations, the loop heat pipe cooling system may include or correspond to a thermosyphon. The loop heat pipe cooling system includes a steam line 363, a liquid line 364, an evaporator 380, and a condenser 382. The evaporator 380 includes a liquid storage chamber 383 and a capillary core 384. The evaporator 380 is configured to receive heat from a heat source, such as the die 108. Based on the received heat, liquid in the evaporator 380 is converted to steam. For example, liquid from the liquid storage chamber 383 is provided to the capillary core where the liquid can be converted to steam. The steam is provided to the steam line 363 and travels, via the steam line to the condenser 382. The condenser 382 is configured to convert the steam to a liquid and dissipate heat. The liquid formed by the condenser 382 is provided to the liquid line 364 and the liquid then travels, via the liquid line 364, to the liquid storage chamber 383 of the evaporator 380.

FIG. 3F illustrates an example of a cross-sectional profile view of an exemplary device that includes the two-phase thermal management device 110. As illustrated in FIG. 3, the lid 125 is coupled to an interface layer 122 such that the lid 125 is thermally coupled to the die 108. The lid 125 includes a base portion 375 and the two-phase thermal management device 110.

In some implementations, the base portion 375 includes one or more layers, such as one or more layers of a conductive material. The conductive material may include copper, aluminum, or a combination thereof, as illustrative, non-limiting examples. In some examples, the base portion 375 includes a first layer and a second layer, and the two-phase thermal management device is positioned between the first layer and the second layer. Additionally, or alternatively, the base portion 375 may encapsulate the two-phase thermal management device. For example, the base structure may include or be a copper structure that surrounds a cavity (e.g., a cavity 376) of the two-phase thermal management device 110. In other implementations, lid 125 may not include the base portion 375 and an entirety of the lid 125 is the two-phase thermal management device.

The base portion 375 and/or the two-phase thermal management device 110 may define a cavity 376 that is configured to house a working fluid. In some implementations, the two-phase thermal management device 110 includes one or more pipes/conduits that define the cavity 376.

FIG. 3G illustrates an example of a cross-sectional view of the two-phase thermal management device 110 of FIG. 3F. For example, the lid 125 includes the base portion 375 and the two-phase thermal management device 110. The two-phase thermal management device 110 includes a heat pipe, such as a heat pipe having a serpentine shape. The heat pipe of the two-phase thermal management device 110 defines the cavity 376 that includes a working fluid. A first portion of the two-phase thermal management device 110 includes an evaporator portion 380 and a second portion of the two-phase thermal management device 110 includes a condenser portion 382. The evaporator portion 380 is configured to receive heat from a heat source, such as the die 108. Based on the received heat, the working fluid is converted from a liquid state to a vapor state. The working fluid in the vapor state may travel to the condenser portion 382 where the working fluid is converted from the vapor state to the liquid state.

FIG. 3H illustrates another example of a cross-sectional view of the two-phase thermal management device 110 of FIG. 3F. For example, the lid 125 includes the base portion 375 and the two-phase thermal management device 110. The two-phase thermal management device 110 may define one or more cavities 376 that includes a working fluid. A first portion of the two-phase thermal management device 110 includes an evaporator portion 380 and a second portion of the two-phase thermal management device 110 includes a condenser portion 382. The evaporator portion 380 is configured to receive heat from a heat source, such as the die 108. Based on the received heat, the working fluid is converted from a liquid state to a vapor state. The working fluid in the vapor state may travel to the condenser portion 382 where the working fluid is converted from the vapor state to the liquid state.

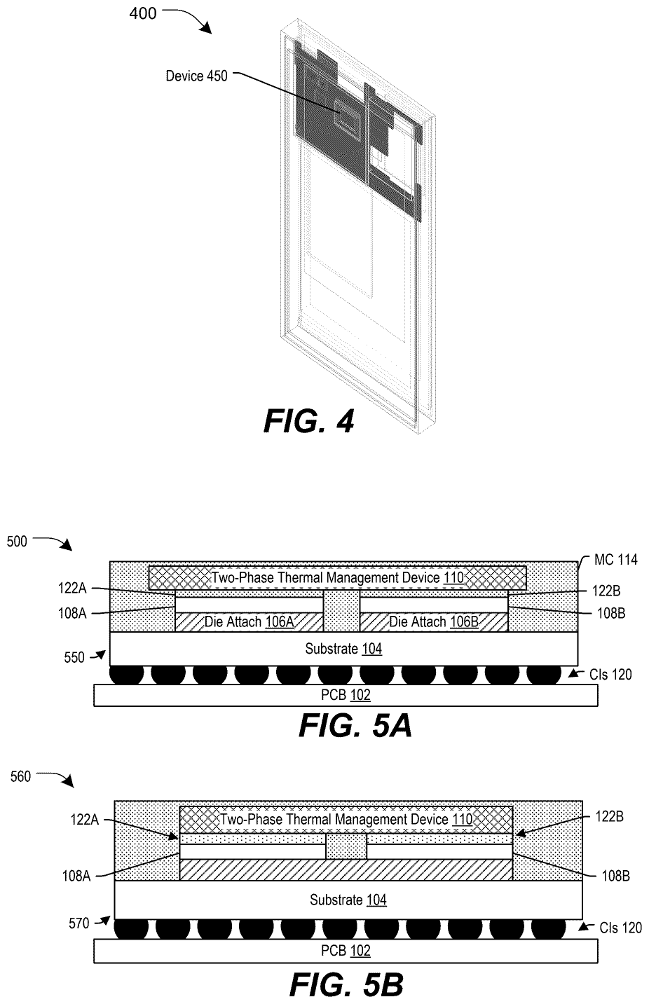

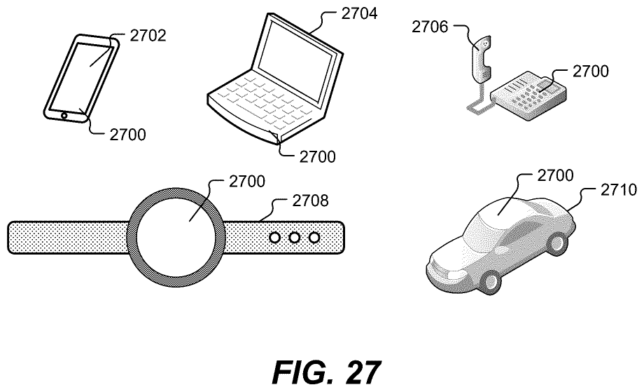

FIG. 4 illustrates a device 450 integrated in a mobile device 400. The device 450 may include the device 100 of FIG. 1, the device 200 of FIG. 2, the device 1500 of FIG. 15, the device 1600 of FIG. 16, the device 1700 of FIG. 17, the device 1800 of FIG. 18, or a combination thereof. Additionally, or alternatively, the device 450 may include one or more devices as described further herein at least with reference to FIGS. 19A-22D. In some implementations, the device 450 can be integrated in a smartphone, a tablet computer, a fixed location terminal device, an automobile, a wearable electronic device, a laptop computer, or some combination thereof, as described in more detail below with reference to FIG. 27. As described with reference to FIGS. 1-3, the device 450 includes the mold compound embedded two-phase thermal management device 110 to provide improved thermal distribution for the mobile device 400. As described with reference to FIG. 3 or 15-18, the device 450 includes the lid 125 having the two-phase thermal management device 110 to provide improved thermal distribution for the mobile device 400. A technical advantage of the two-phase thermal management device 110 is to improve performance, reduce die temperature, or both. Additionally, or alternatively, a technical advantage of the lid 125 is to improve resistance to warpage that may result from heat generated by a die.

FIG. 5A illustrates a cross-sectional profile view of a particular implementation of a device 500 that includes a single mold compound embedded two-phase thermal management device (e.g., the two-phase thermal management device 110) thermally coupled to multiple dies. For example, the two-phase thermal management device 110 is thermally coupled to a die 108A and a die 108B.

The device 500 of FIG. 5A includes many of the same components and features as are described above with reference to FIG. 1. Such components and features are physically and operationally the same as described above with reference to FIG. 1 and are labeled in FIG. 5A using the same reference numbers.

The device 500 includes PLs 550 attached via the CIs 120 to the PCB 102. A plurality of dies 108, such as a die 108A and a die 108B, are at least partially embedded in the mold compound 114 of the PLs 550. An interface layer 122 is formed between the two-phase thermal management device 110 and each of the multiple dies 108. For example, an interface layer 122A (e.g., a layer of the mold compound 114) is formed between the two-phase thermal management device 110 and the die 108A. As another example, an interface layer 122B (e.g., a layer of the mold compound 114) is formed between the two-phase thermal management device 110 and the die 108B. The two-phase thermal management device 110 thermally coupled to two dies 108 is provided as an illustrative example, in other examples the two-phase thermal management device 110 can be coupled to fewer than two dies 108 or more than two dies 108.

FIG. 5B illustrates a cross-sectional profile view of a particular implementation of a device 560 that includes a single mold compound embedded two-phase thermal management device (e.g., the two-phase thermal management device 110) thermally coupled to multiple dies. For example, the two-phase thermal management device 110 is thermally coupled to the die 108A and the die 108B.

The device 560 of FIG. 5B includes many of the same components and features as are described above with reference to FIG. 5A. Such components and features are physically and operationally the same as described above with reference to FIG. 5A and are labeled in FIG. 5B using the same reference numbers.

The device 560 includes PLs 570 attached via the CIs 120 to the PCB 102. The interface layer 122 of the PLs 570 includes a thermal interface layer (e.g., an epoxy layer) between the two-phase thermal management device 110 and each of the multiple dies 108. For example, an interface layer 122A is formed between the two-phase thermal management device 110 and the die 108A. As another example, an interface layer 122B is formed between the two-phase thermal management device 110 and the die 108B. The two-phase thermal management device 110 thermally coupled to two dies 108 is provided as an illustrative example, in other examples the two-phase thermal management device 110 can be coupled to fewer than two dies 108 or more than two dies 108.

FIG. 6A illustrates a cross-sectional profile view of a particular implementation of a device 600 that includes multiple mold compound embedded two-phase thermal management devices thermally coupled to a single die (e.g., the die 108). For example, the die 108 is thermally coupled to a two-phase thermal management device 110A, a two-phase thermal management device 110B, and a two-phase thermal management device 110C.

The device 600 of FIG. 6A includes many of the same components and features as are described above with reference to FIG. 1. Such components and features are physically and operationally the same as described above with reference to FIG. 1 and are labeled in FIG. 6A using the same reference numbers.

The device 600 includes PLs 650 attached via the CIs 120 to the PCB 102. A plurality of two-phase thermal management devices 110, such as a two-phase thermal management device 110A, a two-phase thermal management device 110B, and a two-phase thermal management device 110C, are embedded in the mold compound 114 of the PLs 650. An interface layer 122 is formed between each of the two-phase thermal management devices 110 and the die 108. For example, an interface layer 122A (e.g., a layer of the mold compound 114) is formed between the die 108 and the two-phase thermal management device 110A. As another example, an interface layer 122B (e.g., a layer of the mold compound 114) is formed between the die 108 and the two-phase thermal management device 110B. As yet another example, an interface layer 122C (e.g., a layer of the mold compound 114) is formed between the die 108 and the two-phase thermal management device 110C. The die 108 thermally coupled to three two-phase thermal management devices 110 is provided as an illustrative example, in other examples the die 108 can be coupled to fewer than three two-phase thermal management devices 110 or more than three two-phase thermal management devices 110.

FIG. 6B illustrates a cross-sectional profile view of a particular implementation of a device 660 that includes multiple mold compound embedded device two-phase thermal management devices thermally coupled to a single die (e.g., the die 108). For example, the die 108 is thermally coupled to the two-phase thermal management device 110A, the two-phase thermal management device 110B, and the two-phase thermal management device 110C.

The device 660 of FIG. 6B includes many of the same components and features as are described above with reference to FIG. 6A. Such components and features are physically and operationally the same as described above with reference to FIG. 6A and are labeled in FIG. 6B using the same reference numbers.

The device 660 includes PLs 670 attached via the CIs 120 to the PCB 102. The interface layer 122 of the PLs 670 includes a thermal interface layer (e.g., an epoxy layer) between each of the two-phase thermal management devices 110 and the die 108. For example, each of the two-phase thermal management device 110A, the two-phase thermal management device 110B, and the two-phase thermal management device 110C is formed on an interface layer 122 that is formed on the die 108.

The die 108 thermally coupled to three two-phase thermal management devices 110 is provided as an illustrative example, in other examples the die 108 can be coupled to fewer than three two-phase thermal management devices 110 or more than three two-phase thermal management devices 110.

FIG. 7A illustrates a cross-sectional profile view of a particular implementation of a device 700 that includes multiple mold compound embedded two-phase thermal management devices thermally coupled to multiple dies. For example, a die 108A is thermally coupled to a two-phase thermal management device 110A and a two-phase thermal management device 110B. As another example, a die 108B is thermally coupled to the two-phase thermal management device 110B and a two-phase thermal management device 110C.

The device 700 of FIG. 7A includes many of the same components and features as are described above with reference to FIG. 1. Such components and features are physically and operationally the same as described above with reference to FIG. 1 and are labeled in FIG. 7A using the same reference numbers.

The device 700 includes PLs 750 attached via the CIs 120 to the PCB 102. A plurality of two-phase thermal management devices 110, such as a two-phase thermal management device 110A, a two-phase thermal management device 110B, and a two-phase thermal management device 110C, are embedded in the mold compound 114 of the PLs 750. A plurality of dies 108, such as a die 108A and a die 108B, are at least partially embedded in the mold compound 114. An interface layer 122 is formed between each of the dies 108 and one or more of the two-phase thermal management devices 110. For example, an interface layer 122A (e.g., a layer of the mold compound 114) is formed between the die 108A and each of the two-phase thermal management device 110A and the two-phase thermal management device 110B. As another example, an interface layer 122B (e.g., a layer of the mold compound 114) is formed between the die 108B and each of the two-phase thermal management device 110B and the two-phase thermal management device 110C. Two dies 108 thermally coupled to three two-phase thermal management devices 110 is provided as an illustrative example, in other examples fewer than two dies 108 or more than two dies 108 can be thermally coupled to fewer than three two-phase thermal management devices 110 or more than three two-phase thermal management devices 110.

FIG. 7B illustrates a cross-sectional profile view of a particular implementation of a device 760 that includes multiple mold compound embedded two-phase thermal management devices thermally coupled to multiple dies. For example, a die 108A is thermally coupled to a two-phase thermal management device 110A. As another example, a die 108B is thermally coupled to a two-phase thermal management device 110B.

The device 760 of FIG. 7B includes many of the same components and features as are described above with reference to FIG. 7A. Such components and features are physically and operationally the same as described above with reference to FIG. 7A and are labeled in FIG. 7B using the same reference numbers.

The device 760 includes PLs 770 attached via the CIs 120 to the PCB 102. The interface layer 122 of the PLs 770 includes a thermal interface layer (e.g., an epoxy layer) between each of the dies 108 and a corresponding one of the two-phase thermal management devices 110. For example, an interface layer 122A is formed between the die 108A and the two-phase thermal management device 110A. As another example, an interface layer 122B is formed between the die 108B and the two-phase thermal management device 110B. Two dies 108 thermally coupled to two two-phase thermal management devices 110 is provided as an illustrative example, in other examples fewer than two dies 108 or more than two dies 108 can be thermally coupled to fewer than two two-phase thermal management devices 110 or more than two two-phase thermal management devices 110.

FIGS. 19A-D, 20A-D, 21A-D, and 22A-D illustrate cross-sectional profile views of examples of devices that include two-phase thermal management devices. The devices of FIGS. 19A-D, 21A-D, 22A-D, and 22A-D include many of the same components and features as are described above with reference to FIGS. 15, 16, 17, and 18, respectively. Such components and features are physically and operationally the same as described above with reference to FIGS. 15-18 and are labeled, respectively, in FIGS. 19A-D, 21A-D, 22A-D, and 22A-D using the same reference numbers.

FIGS. 19A, 20A, 21A, and 22A each illustrate a cross-sectional profile view of a particular implementation of a respective device that includes a single two-phase thermal management device (e.g., the two-phase thermal management device 110) thermally coupled to multiple dies. For example, FIG. 19A includes a device 1900, FIG. 20A includes a device 2000, FIG. 21A includes a device 2100, and FIG. 22A includes a device 2200. The devices 1900, 2000, 2100, and 2200 each include multiple dies 108, such as a die 108A and a die 108B. The lid 125, including the two-phase thermal management device 110, is thermally coupled to the die 108A and the die 108B. Accordingly, the two-phase thermal management device 110 is thermally coupled to a die 108A and a die 108B. The die 108A is coupled to the substrate 104 via die attach 106A and the die 108B is coupled to the substrate 104 via the die attach 106B. An interface layer 122 is positioned between the lid 125 and each of the multiple dies 108. For example, an interface layer 122A is positioned between the lid 125 and the die 108A. As another example, an interface layer 122B is positioned between the lid 125 and the die 108B. Although each of the devices 1900, 2000, 2100, and 2200 is described as the lid 125 (e.g., the two-phase thermal management device 110) being thermally coupled to two dies 108, in other examples the lid 125 (e.g., the two-phase thermal management device 110) can be coupled to more than two dies 108.

FIGS. 19B, 20B, 21B, and 22B each illustrate a cross-sectional profile view of a particular implementation of a respective device that includes a single two-phase thermal management device (e.g., the two-phase thermal management device 110) thermally coupled to multiple dies. For example, FIG. 19B includes a device 1920, FIG. 20B includes a device 2020, FIG. 21B includes a device 2120, and FIG. 22B includes a device 2220. The devices 1920, 2020, 2120, and 2220 each include multiple dies 108, such as a die 108A and a die 108B. The lid 125, including the two-phase thermal management device 110, is thermally coupled to the die 108A and the die 108B. Accordingly, the two-phase thermal management device 110 is thermally coupled to a die 108A and a die 108B. The die 108A is coupled to the substrate 104 via die attach 106A and the die 108B is coupled to the substrate 104 via the die attach 106B. An interface layer 122 is positioned between the lid 125 and each of the multiple dies 108. For example, an interface layer 122A is positioned between the lid 125 and the die 108A. As another example, an interface layer 122B is positioned between the lid 125 and the die 108B. Although each of the devices 1920, 2020, 2120, and 2220 is described as the lid 125 (e.g., the two-phase thermal management device 110) being thermally coupled to two dies 108, in other examples the lid 125 (e.g., the two-phase thermal management device 110) can be coupled to more than two dies 108.

FIGS. 19C, 20C, 21C, and 22C each illustrate a cross-sectional profile view of a particular implementation of a respective device that includes multiple two-phase thermal management devices thermally coupled to a single die (e.g., the die 108). For example, FIG. 19C includes a device 1940, FIG. 20C includes a device 2040, FIG. 21C includes a device 2140, and FIG. 22C includes a device 2240. The devices 1940, 2040, 2140, and 2240 each include the lid 125 having multiple two-phase thermal management devices 110, such as a two-phase thermal management device 110A and a two-phase thermal management device 110B. The lid 125, including the multiple two-phase thermal management devices 110, is thermally coupled to the die 108. Accordingly, each of the multiple two-phase thermal management devices 110 is thermally coupled to the die. The die 108 is coupled to the substrate 104 via the die attach. An interface layer 122 is positioned between the lid 125 and the die 108. Although each of devices 1940, 2040, 2140, and 2240 is described as the lid 125 including two two-phase thermal management devices 110, in other examples the lid 125 may include more than two two-phase thermal management devices 110.

FIGS. 19D, 20D, 21D, and 22D each illustrate a cross-sectional profile view of a particular implementation of a respective device that includes multiple mold compound embedded two-phase thermal management devices thermally coupled to multiple dies. For example, FIG. 19D includes a device 1960, FIG. 20D includes a device 2060, FIG. 21D includes a device 2160, and FIG. 22D includes a device 2260. The devices 1960, 2060, 2160, and 2260 each include the lid 125 having multiple two-phase thermal management devices 110, such as a two-phase thermal management device 110A and a two-phase thermal management device 110B. The lid 125, including the multiple two-phase thermal management devices 110, is thermally coupled to the die 108A and the die 108B. Accordingly, the two-phase thermal management device 110 is thermally coupled to a die 108A and a die 108B. The multiple dies 108 are coupled to the substrate 104 via die attach 106. An interface layer 122 is positioned between the lid 125 and each of the multiple dies 108. For example, an interface layer 122A is positioned between the lid 125 and the die 108A. As another example, an interface layer 122B is positioned between the lid 125 and the die 108B. Although each of the devices 1960, 2060, 2160, and 2260 is described as the lid 125 (e.g., the two-phase thermal management device 110) being thermally coupled to two dies 108, in other examples the lid 125 (e.g., the two-phase thermal management device 110) can be coupled to more than two dies 108. Additionally, or alternatively, although each of the devices 1960, 2060, 2160, and 2260 is described as the lid 125 including two two-phase thermal management devices 110, in other examples the lid 125 may include more than two two-phase thermal management devices 110.

It should be understood that one or more of the devices of FIG. 19A-D, 20A-D, 21A-D, or 22A-D may include additional components, other components, fewer components, or a combination thereof, to support the functionality described herein. As non-limiting examples, one or more of the devices of FIG. 19A-D, 20A-D, 21A-D, or 22A-D may include additional IC devices, additional layers, additional dies, additional two-phase thermal management devices, additional packages, additional interconnects, additional structures, other components, different components, or a combination thereof, to support the functionality and technical advantages disclosed herein.

In some implementations, one or more of the devices of FIG. 19A-D or 20A-D may include mold compound, such as the mold compound 114. The mold compound may be positioned with the cavity 127 along with the semiconductor die, a die attach, and an interface layer. Additionally, or alternatively, the mold compound may be coupled to the substrate 104, a side surface of the die 108, a side surface of the die attach 106 positioned between the substrate 104 and the die 108, or a combination thereof. In some such implementations, the mold compound at least partially encapsulates the die attach 106 and/or the die 108. In some embodiments, the mold compound is interposed between the interface layer 122 and the substrate 104. Additionally, or alternatively, the interface layer 122 may be interposed between the mold compound and the lid 125.

In some implementations, one or more of the devices of FIG. 19A-D or 20A-D may include one or more additional walls. For example, an additional wall may be positioned in the cavity 127 and coupled to the substrate 104, the lid 125, or a combination thereof. To illustrate, the additional wall may be coupled to the substrate 104 or the lid 125 as described with reference to the wall 126 of FIG. 15. The additional wall may increase resistance to package warpage and/or provide structural support for one or more of the devices of FIG. 19A-D or 20A-D.

In some implementations, one or more of the devices of FIGS. 19A-D that include the lid 125 and the wall 126 or one or more devices of FIG. 20AD or 21A-D that include the lid 125 having the wall portion 136 may be configured and/or coupled to form a shielding can to isolate the die 108 by creating a Faraday cage directly on the substrate 104. In other implementations, one or more of the devices of FIG. 19A-D, 20A-D, 21A-D, or 22A-D may be coupled to a PCB and the device is enclosed in a shielding can. For example, the shielding can may isolate the die 108 by creating a Faraday cage directly on the PCB.

In some implementations, one or more of the devices of FIG. 19A-D, 20A-D, 21A-D, or 22A-D may not include the CIs 120. Although each of the devices of FIG. 19A-D, 20A-D, 21A-D, or 22A-D is shown as including the CIs 120, in other implementations, one or more of the devices of FIG. 19A-D, 20A-D, 21A-D, or 22A-D may not have or include the CIs 120.

The example devices of FIGS. 1-7B and 15-22D can be integrated with or included within a wide variety of other devices. For example, a device that includes one or more of the mold compound embedded two-phase thermal management devices disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the device of FIG. 1, 2, 5A-B, 6A-B, 7A-B, 15-18, 19A-D, 20A-D, 21A-D, or 22A-D can operate as any of these components (or a combination of these components) that includes active circuitry.

### Exemplary Sequences for Fabricating a Packaged Device/IC Device Including a Two-Phase Thermal Management Device

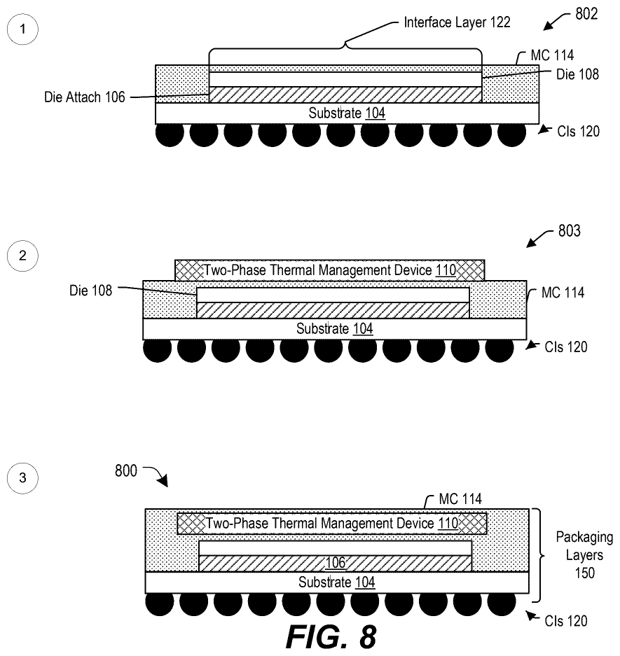

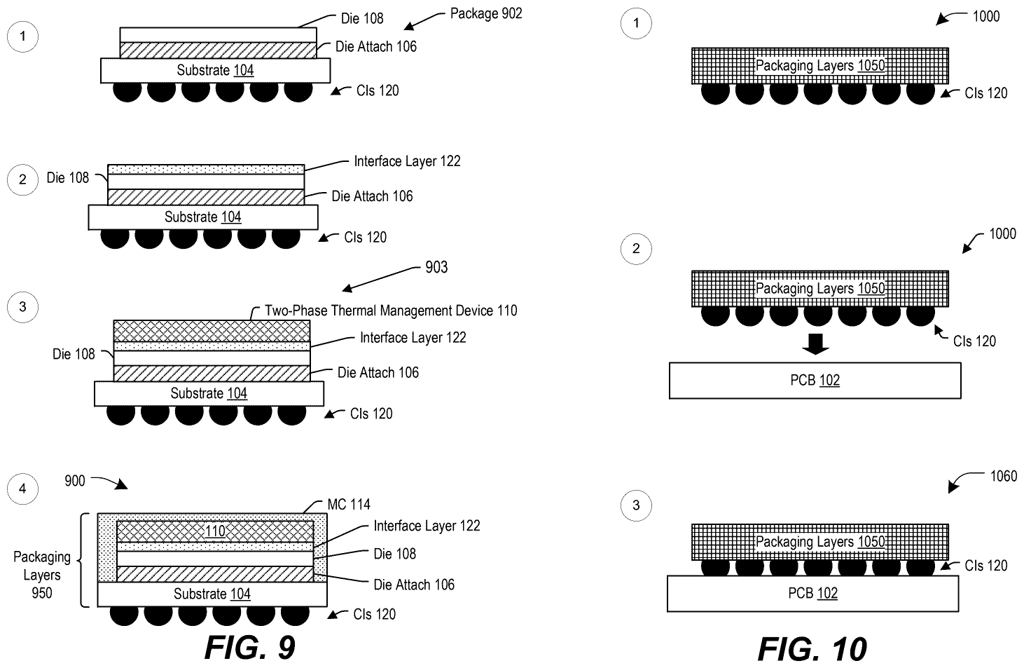

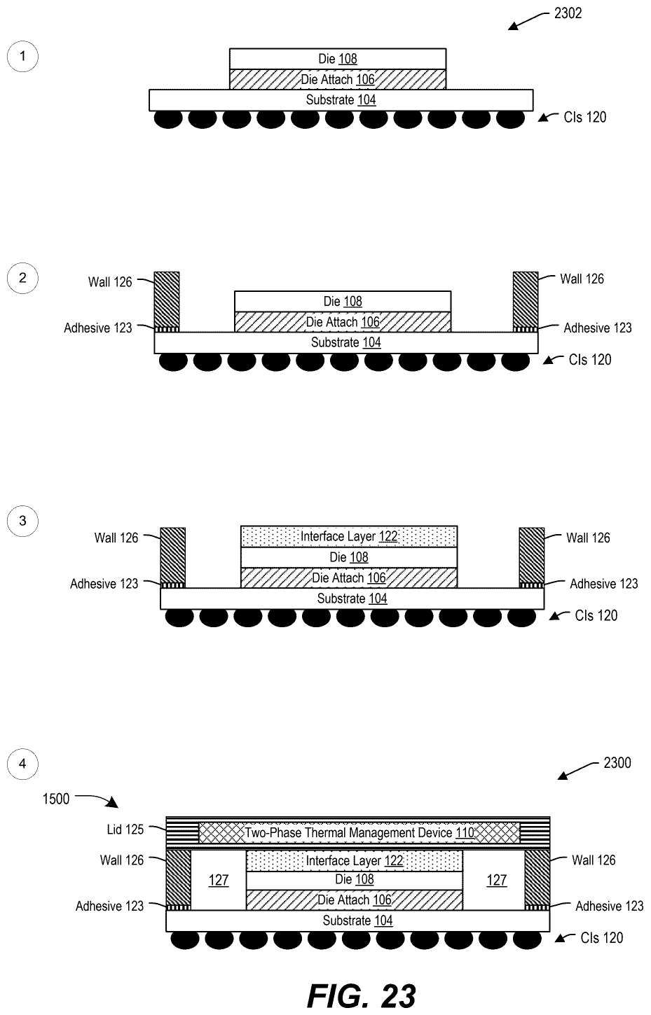

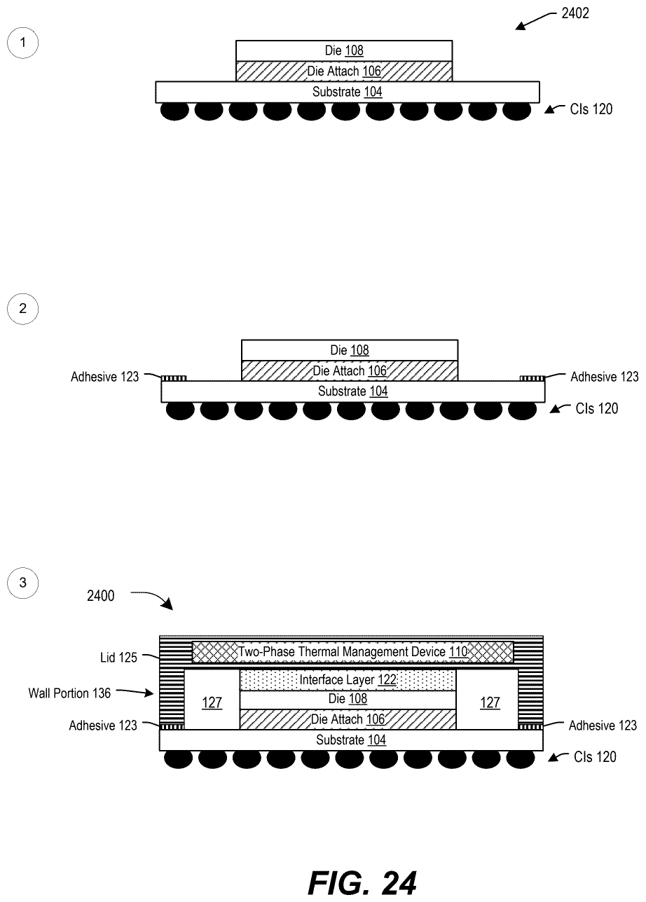

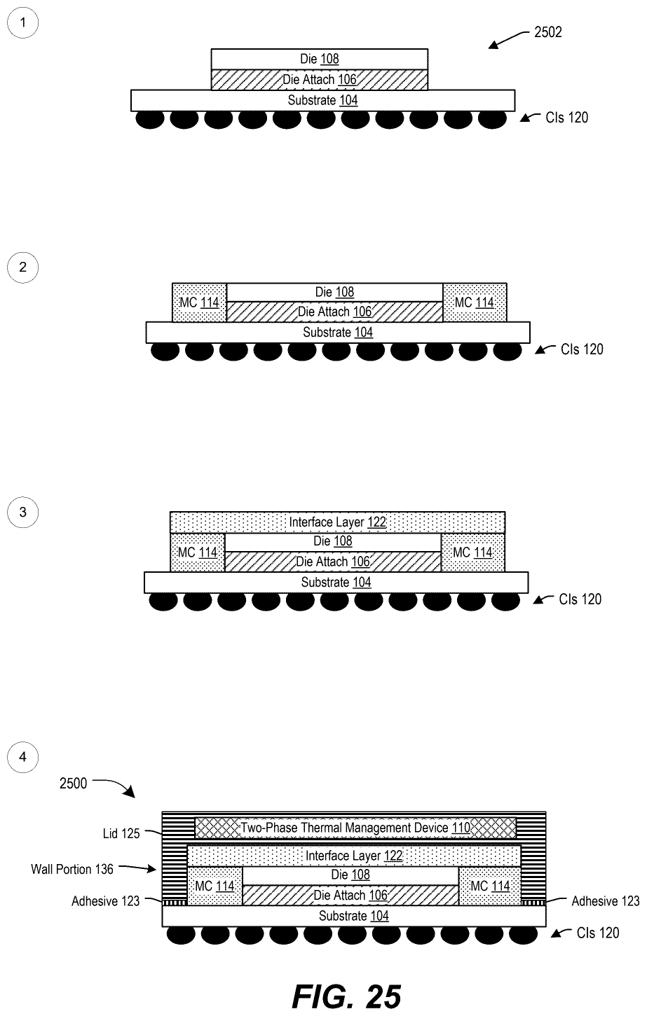

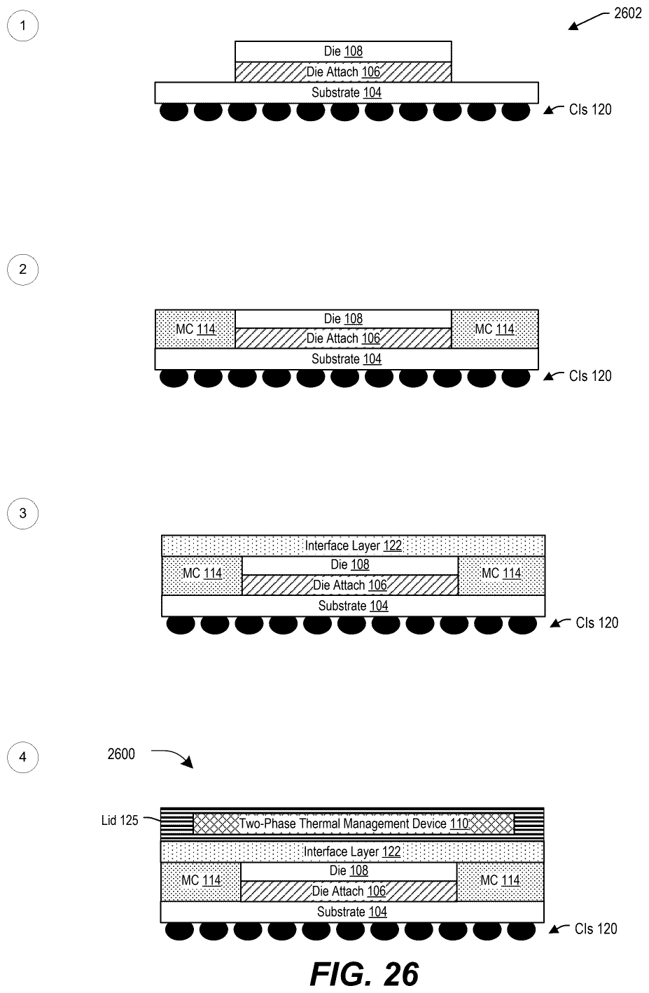

In some implementations, fabricating a device including a two-phase thermal management device includes several processes. For example, fabricating a device including a mold compound embedded two-phase thermal management device (e.g., any of the devices 100, 200, 500, 560, 600, 660, 700, or 760) includes several processes. FIG. 8 illustrates an exemplary sequence for fabricating or providing a device that includes a mold compound embedded two-phase thermal management device, as described with reference to FIG. 1. FIG. 9 illustrates an exemplary sequence for fabricating or providing a device that includes a mold compound embedded two-phase thermal management device, as described with reference to FIG. 2. As another example, fabricating a device including a lid having a two-phase thermal management device (e.g., any of the devices of FIG. 15-18, 19A-D, 20A-D, 21A-D, or 22A-D) includes several processes. FIG. 23 illustrates an exemplary sequence for fabricating an exemplary device that includes a two-phase thermal management device, as described with reference to FIG. 15. FIG. 24 illustrates an exemplary sequence for fabricating an exemplary device that includes a two-phase thermal management device, as described with reference to FIG. 16. FIG. 25 illustrates an exemplary sequence for fabricating an exemplary device that includes a two-phase thermal management device, as described with reference to FIG. 17. FIG. 26 illustrates an exemplary sequence for fabricating an exemplary device that includes a two-phase thermal management device, as described with reference to FIG. 18. FIG. 10 illustrates an exemplary sequence for fabricating or providing a device that includes a two-phase thermal management device, such as a device that includes a mold compound embedded two-phase thermal management device, as described with reference to FIGS. 1 and 2, or a device that includes a lid having a two-phase thermal management device, as described at least with reference to FIGS. 15-18.

In some implementations, the sequence of FIGS. 8, 10, and 11 may be used to provide (e.g., during fabrication of) the device 100 of FIG. 1. In some implementations, the sequence of FIGS. 9-11 may be used to provide (e.g., during fabrication of) the device 200 of FIG. 2. In some implementations, the sequence of FIG. 23 or 10 may be used to provide (e.g., during fabrication of) the device 1500 of FIG. 15. In some implementations, the sequence of FIG. 24 or 10 may be used to provide (e.g., during fabrication of) the device 1600 of FIG. 16. In some implementations, the sequence of FIG. 25 or 10 may be used to provide (e.g., during fabrication of) the device 1700 of FIG. 17. In some implementations, the sequence of FIG. 26 or 10 may be used to provide (e.g., during fabrication of) the device 1800 of FIG. 18.

It should be noted that the sequences of FIG. 8-11 or 23-26 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequences, which are numbered (using circled numbers) in FIG. 8-11 or 23-26. Each of the various stages of the sequence illustrated in FIG. 8-11 or 23-26 shows one or more integrated devices being formed. In other implementations, a single integrated device may be formed or a plurality of integrated devices can be formed concurrently.

Referring to FIG. 8, Stage 1 of FIG. 8 illustrates a state after obtaining a package 802. The package 802 includes the die 108 attached via the die attach 106 to a first surface of the substrate 104. The CIs 120 are attached to a second surface of the substrate 104. The die 108 and the die attach 106 are at least partially encapsulated in the MC 114. A layer of the MC 114 that is on the die 108 corresponds to the interface layer 122. In some implementations, a thinning process is applied to the MC 114 to achieve a target thickness of the interface layer 122. In a particular aspect, the thinning process includes at least one of chemical mechanical planarization (CMP), plasma etching, laser ablation, mechanical grinding, chemical etching, polishing, thermal reflow, or a combination thereof.

Stage 2 illustrates a state after attaching a two-phase thermal management device 110 on a surface of the mold compound 114. For example, as part of Stage 2, the two-phase thermal management device 110 is positioned to at least partially align with the interface layer 122. In a particular aspect, an adhesive material is applied to the surface of the mold compound 114 prior to placing the two-phase thermal management device 110 on the adhesive material. In some implementations, if the adhesive material includes a thermal adhesive, a curing process is applied to attach the two-phase thermal management device 110 to the mold compound 114.

In some implementations, after the two-phase thermal management device is attached, a device 803 (e.g., an integrated circuit) is obtained. The device 803 includes the die 108 and the two-phase thermal management device 110 coupled to the die 108. The two-phase thermal management device 110 may include a sealed two-phase thermal management device. Additionally, or alternatively, the two-phase thermal management device may define a portion of an outer surface of the device 803. In some implementations, the two-phase thermal management device 110 constitutes or is included in a lid (e.g., the lid 125) of the device 803. The device 803 also includes the interface layer 122 positioned between the die 108 and the two-phase thermal management device 110. In some implementations, the interface layer 122 is in contact with the die 108, the two-phase thermal management device 110, or both. The mold compound 114 may define a portion of an outer surface of the device 803. The mold compound is coupled to the substrate 104, a side surface of the die 108, a side surface of the die attach 106 (positioned between the substrate 104 and the die 108), or a combination thereof.

Stage 3 illustrates a state after applying the mold compound 114 to encapsulate the two-phase thermal management device 110. For example, as part of Stage 3, the mold compound 114 is applied as a liquid or paste, and subsequently cured (e.g., by exposure to heat, a chemical curing agent, light, etc.) to encapsulate the two-phase thermal management device 110. The mold compound 114 solidifies with the two-phase thermal management device 110 embedded in the mold compound 114.

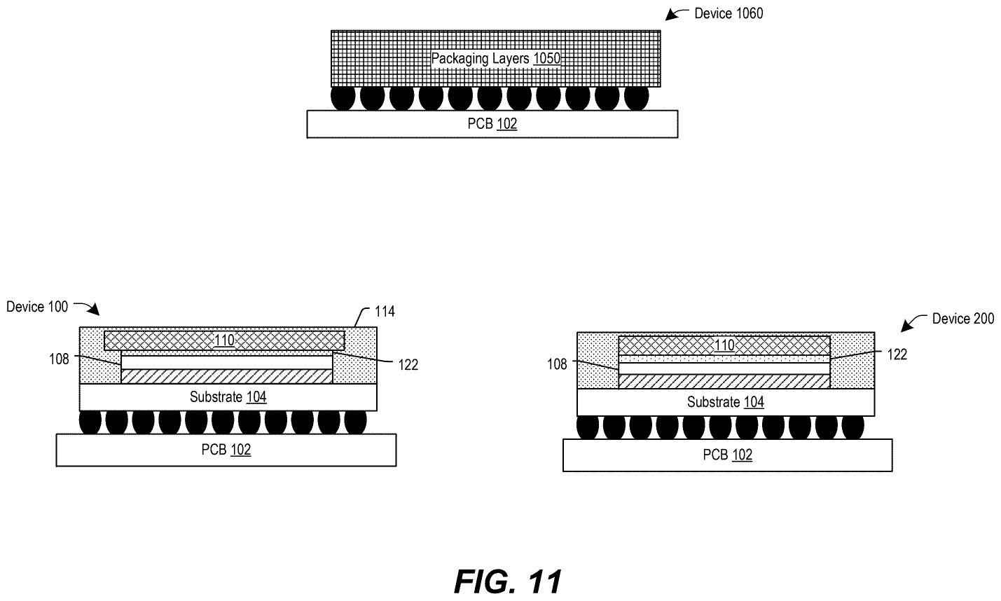

Formation of a device 800 (e.g., a device including a mold embedded two-phase thermal management device) is complete after Stage 3 of FIG. 8. The device 800 can be used to form the device 100 of FIG. 1, as further described with reference to FIGS. 10-11.

Although certain Stages are illustrated in FIG. 8 in forming the device 800, other processes can be included in the fabrication of the device 800 without departing from the scope of the subject disclosure. For example, fabricating the device 800 can include obtaining the package 802 with multiple dies, such as a die 108A and a die 108B attached to the substrate 104 and encapsulated in the mold compound 114, attaching the two-phase thermal management device 110 to a surface of the mold compound 114 such that the two-phase thermal management device 110 is at least partially aligned with the multiple dies 108, and encapsulating the two-phase thermal management device 110 in the mold compound 114. In this example, the device 800 can be used to form the device 500 of FIG. 5A, as further described with reference to FIGS. 10-11.

Additionally, or alternatively, fabricating the device 800 can include, after obtaining the package 802 in Stage 1 of FIG. 8, attaching multiple two-phase thermal management devices 110 to a surface of the mold compound 114 such that each of the two-phase thermal management devices 110 is at least partially aligned with the die 108, and encapsulating the two-phase thermal management devices 110 in the mold compound 114. In this example, the device 800 can be used to form the device 600 of FIG. 6A, as further described with reference to FIGS. 10-11.

Additionally, or alternatively, fabricating the device 800 can include obtaining the package 802 with multiple dies, such as a die 108A and a die 108B attached to the substrate 104 and encapsulated in the mold compound 114, attaching multiple two-phase thermal management devices 110 to a surface of the mold compound 114 such that each of the two-phase thermal management devices 110 is at least partially aligned with at least one of the multiple dies 108, and encapsulating the two-phase thermal management devices 110 in the mold compound 114. In this example, the device 800 can be used to form the device 700 of FIG. 7A, as further described with reference to FIGS. 10-11.

Referring to FIG. 9, Stage 1 of FIG. 9 illustrates a state after obtaining a package 902. The package 902 includes the die 108 attached via the die attach 106 to a first surface of the substrate 104. The CIs 120 are attached to a second surface of the substrate 104.

Stage 2 illustrates a state after applying a thermal interface layer (e.g., an epoxy layer) as an interface layer 122 to a surface of the die 108. For example, applying the interface layer 122 can include dispensing or coating the interface layer 122 (e.g., an epoxy layer) on the surface of the die 108 and using curing processes to cure the interface layer 122. In a particular aspect, curing processes can include oven curing, hot plate curing, or using a reflow oven. UV-curable epoxies are exposed to ultraviolet light for curing.

Stage 3 illustrates a state after attaching a two-phase thermal management device 110 on a surface of the interface layer 122. For example, as part of Stage 3, the two-phase thermal management device 110 is positioned to at least partially align with the interface layer 122. In some aspects, the interface layer 122 is cured after placing the two-phase thermal management device 110 on the interface layer 122.

In some implementations, after the two-phase thermal management device is attached, a device 903 (e.g., an integrated circuit) is obtained. The device 903 includes the die 108 and the two-phase thermal management device 110 coupled to the die 108. The two-phase thermal management device 110 may include a sealed two-phase thermal management device. Additionally, or alternatively, the two-phase thermal management device 110 may define a portion of an outer surface of the device 903. In some implementations, the two-phase thermal management device 110 constitutes or is included in a lid (e.g., the lid 125) of the device 903. The device 903 also includes the interface layer 122 positioned between the die 108 and the two-phase thermal management device 110. In some implementations, the interface layer 122 is in contact with the die 108, the two-phase thermal management device 110, or both.

Stage 4 illustrates a state after applying the mold compound 114 to encapsulate the two-phase thermal management device 110. For example, as part of Stage 3, the mold compound 114 is applied as a liquid or paste, and subsequently cured (e.g., by exposure to heat, a chemical curing agent, light, etc.) to encapsulate the two-phase thermal management device 110, the interface layer 122, the die 108, and the die attach 106. The mold compound 114 solidifies with the two-phase thermal management device 110, the interface layer 122, the die 108, and the die attach 106 embedded in the mold compound 114. Packaging layers 950 include the two-phase thermal management device 110, the interface layer 122, the die 108, and the die attach 106 embedded in the mold compound 114 and formed on the substrate 104.

Formation of a device 900 (e.g., a device including a mold embedded two-phase thermal management device) is complete after Stage 4 of FIG. 9. The device 900 can be used to form the device 200 of FIG. 2, as further described with reference to FIGS. 10-11.

Although certain Stages are illustrated in FIG. 9 in forming the device 900, other processes can be included in the fabrication of the device 900 without departing from the scope of the subject disclosure. For example, fabricating the device 900 can include obtaining the package 902 with multiple dies, such as a die 108A and the die 108B attached to the substrate 104, applying interface layers to each of the multiple dies (e.g., an interface layer 122A to the die 108A and an interface layer 122B to the die 108B), filling the space between and outside the dies 108 and the interface layers 122 with the mold compound 114, attaching the two-phase thermal management device 110 to the interface layers 122, and encapsulating the two-phase thermal management device 110, the interface layers 122, the dies 108, and the die attach 106 in the mold compound 114. In some examples, the mold compound 114 may be thinned to expose a surface of the interface layers 122 prior to attaching the two-phase thermal management device 110 to the interface layers 122. In this example, the device 900 can be used to form the device 560 of FIG. 5B, as further described with reference to FIGS. 10-11.

Additionally, or alternatively, fabricating the device 900 can include, after applying the interface layer 122 to the die 108 in Stage 2 of FIG. 9, attaching multiple two-phase thermal management devices 110 to a surface of the interface layer 122, and encapsulating the two-phase thermal management devices 110, the interface layer 122, the die 108, and the die attach 106 in the mold compound 114. In this example, the device 900 can be used to form the device 660 of FIG. 6B, as further described with reference to FIGS. 10-11.

Additionally, or alternatively, fabricating the device 900 can include obtaining the package 902 with multiple dies, such as a die 108A and the die 108B attached to the substrate 104, applying interface layers to each of the multiple dies (e.g., an interface layer 122A to the die 108A and an interface layer 122B to the die 108B), attaching two-phase thermal management devices to each of the interface layers (e.g., a two-phase thermal management device 110A to the interface layer 122A and a two-phase thermal management device 110B to the interface layer 122B), and encapsulating the two-phase thermal management devices 110, the interface layers 122, the dies 108, and the die attach 106 in the mold compound 114. In this example, the device 900 can be used to form the device 760 of FIG. 7B, as further described with reference to FIGS. 10-11.

Referring to FIG. 23, Stage 1 of FIG. 23 illustrates a state after obtaining a package 2302. The package 2302 includes the die 108 attached via the die attach 106 to a first surface of the substrate 104. The CIs 120 are attached to a second surface of the substrate 104.

Stage 2 of FIG. 23 illustrates a state after applying an adhesive layer 123 and a wall 126. For example, applying the adhesive layer 123 can include dispensing an adhesive on a surface of the substrate 104. The wall 126 may be coupled to the adhesive. After the wall 126 is coupled to the adhesive, a curing process can be performed to cure the adhesive. In a particular aspect, the curing process can include oven curing, hot plate curing, using a reflow oven, or UV-curing. In some such implementations, the adhesive includes a UV-curable epoxy.

Stage 3 of FIG. 23 illustrates a state after applying a thermal interface layer (e.g., an epoxy layer) as an interface layer 122 to a surface of the die 108. For example, applying the interface layer 122 can include dispensing or coating the interface layer 122 (e.g., an epoxy layer) on the surface of the die 108. In some implementations, after the interface layer 122 is applied, curing processes may be performed to cure the interface layer 122. In a particular aspect, the curing processes can include oven curing, hot plate curing, using a reflow oven, or using a UV-curing process.

Stage 4 of FIG. 23 illustrates a state after attaching a lid 125 including a two-phase thermal management device 110 on a surface of the interface layer 122 and coupling the lid 125 to the wall 126. For example, as part of Stage 4, the lid 125 is positioned on the interface layer 122 and/or the wall 126. In some aspects, the interface layer 122 is cured after placing the lid 125 on the interface layer 122. Additionally, or alternatively, prior to the lid 125 being attached, a coupling material may be applied to the wall 126. In some implementations, the coupling material includes an epoxy.

Formation of a device 2300 is complete after Stage 4 of FIG. 23. The device 2300 can be used to form the device 1500 of FIG. 15. For example, the device 2300 includes the die 108 and the lid 125 coupled to the die 108. The two-phase thermal management device 110 may include a sealed two-phase thermal management device. Additionally, or alternatively, the lid 125 may define a portion of an outer surface of the device 2300. The device 2300 also includes the interface layer 122 positioned between the die 108 and the lid 125. In some implementations, the interface layer 122 is in contact with the die 108, the lid 125, or both.

Referring to FIG. 24, Stage 1 of FIG. 24 illustrates a state after obtaining a package 2402. The package 2402 includes the die 108 attached via the die attach 106 to a first surface of the substrate 104. The CIs 120 are attached to a second surface of the substrate 104.

Stage 2 of FIG. 24 illustrates a state after applying an adhesive layer 123. For example, applying the adhesive layer 123 can include dispensing an adhesive on a surface of the substrate 104. The adhesive may include an epoxy, such as a UV-curable epoxy.

Stage 3 of FIG. 24 illustrates a state after applying a thermal interface layer (e.g., an epoxy layer) as an interface layer 122 to a surface of the die 108, and after attaching a lid 125 including a two-phase thermal management device 110 on a surface of the interface layer 122 and the adhesive layer 123. For example, applying the interface layer 122 can include dispensing or coating the interface layer 122 (e.g., an epoxy layer) on the surface of the die 108. In some implementations, after the lid 125 is applied, curing processes may be performed to cure the interface layer 122 and/or the adhesive layer 123.

Formation of a device 2400 is complete after Stage 3 of FIG. 24. The device 2400 can be used to form the device 1600 of FIG. 16. For example, the device 2400 includes the die 108 and the lid 125 coupled to the die 108. The two-phase thermal management device 110 may include a sealed two-phase thermal management device. Additionally, or alternatively, the lid 125 may define a portion of an outer surface of the device 2300. The device 2400 also includes the interface layer 122 positioned between the die 108 and the lid 125. In some implementations, the interface layer 122 is in contact with the die 108, the lid 125, or both.

Referring to FIG. 25, Stage 1 of FIG. 25 illustrates a state after obtaining a package 2502. The package 2502 includes the die 108 attached via the die attach 106 to a first surface of the substrate 104. The CIs 120 are attached to a second surface of the substrate 104.

Stage 2 of FIG. 25 illustrates a state after applying the mold compound 114. For example, applying the mold compound 114 can include dispensing or coating the mold compound 114 (e.g., a TIM) on the surface of the substrate 104. In some implementations, a thinning process is applied to the mold compound 114. In a particular aspect, the thinning process includes at least one of chemical mechanical planarization (CMP), plasma etching, laser ablation, mechanical grinding, chemical etching, polishing, thermal reflow, or a combination thereof.

Stage 3 of FIG. 25 illustrates a state after applying a thermal interface layer (e.g., an epoxy layer) as an interface layer 122 to a surface of the die 108 and/or the mold compound 114. For example, applying the interface layer 122 can include dispensing or coating the interface layer 122 (e.g., an epoxy layer) on the surface of the die 108 and/or the mold compound 114. In some implementations, after the interface layer 122 is applied, curing processes are performed to cure the interface layer 122. In a particular aspect, the curing processes can include oven curing, hot plate curing, using a reflow oven, or a UV-curing process.

Stage 4 of FIG. 25 illustrates a state after applying an adhesive layer 123 and after attaching a lid 125 including a cooling structure 110 on a surface of the interface layer 122 and the adhesive layer 123. For example, applying the adhesive layer 123 can include dispensing an adhesive on a surface of the substrate 104. In some implementations, after the lid 125 is applied, curing processes may be performed to cure mold compound 114, the interface layer 122, and/or the adhesive layer 123.

Formation of a device 2500 is complete after Stage 4 of FIG. 25. The device 2500 can be used to form the device 1700 of FIG. 17. For example, the device 2500 includes the die 108 and the lid 125 coupled to the die 108. The two-phase thermal management device 110 may include a sealed two-phase thermal management device. Additionally, or alternatively, the lid 125 may define a portion of an outer surface of the device 2300. The device 2500 also includes the interface layer 122 positioned between the die 108 and the lid 125. In some implementations, the interface layer 122 is in contact with the die 108, the lid 125, or both.

Referring to FIG. 26, Stage 1 of FIG. 26 illustrates a state after obtaining a package 2602. The package 2602 includes the die 108 attached via the die attach 106 to a first surface of the substrate 104. The CIs 120 are attached to a second surface of the substrate 104.

Stage 2 of FIG. 26 illustrates a state after applying the mold compound 114. For example, applying the mold compound 114 can include dispensing or coating the mold compound 114 (e.g., a TIM) on the surface of the substrate 104. In some implementations, a thinning process is applied to the mold compound 114. In a particular aspect, the thinning process includes at least one of chemical mechanical planarization (CMP), plasma etching, laser ablation, mechanical grinding, chemical etching, polishing, thermal reflow, or a combination thereof.

Stage 3 of FIG. 26 illustrates a state after applying a thermal interface layer (e.g., an epoxy layer) as an interface layer 122 to a surface of the die 108 and/or the mold compound 114. For example, applying the interface layer 122 can include dispensing or coating the interface layer 122 (e.g., an epoxy layer) on the surface of the die 108 and/or the mold compound 114. In some implementations, after the interface layer 122 is applied, curing processes are performed to cure the interface layer 122. In a particular aspect, the curing processes can include oven curing, hot plate curing, using a reflow oven, or a UV-curing process.

Stage 4 of FIG. 26 illustrates a state after applying an adhesive layer 123 and after attaching a lid 125 including a two-phase thermal management device 110 on a surface of the interface layer 122 and the adhesive layer 123. For example, applying the adhesive layer 123 can include dispensing an adhesive on a surface of the substrate 104. In some implementations, after the lid 125 is applied, curing processes may be performed to cure mold compound 114, the interface layer 122, and/or the adhesive layer 123.

Formation of a device 2600 is complete after Stage 4 of FIG. 26. The device 2600 can be used to form the device 1800 of FIG. 18. For example, the device 2600 includes the die 108 and the lid 125 coupled to the die 108. The two-phase thermal management device 110 may include a sealed two-phase thermal management device. Additionally, or alternatively, the lid 125 may define a portion of an outer surface of the device 2300. The device 2500 also includes the interface layer 122 positioned between the die 108 and the lid 125. In some implementations, the interface layer 122 is in contact with the die 108, the lid 125, or both.

Although certain Stages are illustrated in FIGS. 23-26, other processes can be included in the fabrication illustrated in FIGS. 23-26 without departing from the scope of the subject disclosure. For example, Stage 1 of FIGS. 23-26 can include obtaining a package (e.g., 2302, 2402, 2502, or 2602, respectively) with multiple dies, such as a die 108A and the die 108B attached to the substrate 104. In some such examples, the die attach 106 of the obtained package can include a single die attach for the multiple dies or a separate die attach for each die. Additionally, or alternatively, with reference to Stage 3 of FIGS. 23-26, an interface layer may be applied to each of the multiple dies (e.g., an interface layer 122A to the die 108A and an interface layer 122B to the die 108B). Additionally, or alternatively, with reference to Stage 4 of FIG. 23, 26, or 26 or Stage 3 of FIG. 25, the lid 125 may include multiple two-phase thermal management devices, such as a two-phase thermal management device 110A and a two-phase thermal management device 110B. Accordingly, the Stages illustrated may be used and/or modified to form a device as described with reference to FIG. 15-18, 19A-D, 20A-D, 21A-D, or 22A-D.

Referring to FIG. 10, Stage 1 of FIG. 10 illustrates a state after obtaining a device 1000 that includes packaging layers 1050 electrically connected to CIs 120. In a particular aspect, the packaging layers 1050 correspond to the packaging layers 150 of FIG. 1, the packaging layers 250 of FIG. 2, the packaging layers 550 of FIG. 5A, the packaging layers 570 of FIG. 5B, the packaging layers 650 of FIG. 6A, the packaging layers 670 of FIG. 6B, the packaging layers 750 of FIG. 7A, or the packaging layers 770 of FIG. 7B. Additionally, or alternatively, the device may include or correspond to the device 803 or 903, or a device of FIG. 15-18, 19A-D, 20A-D, 21A-D, or 22A-D.

Stage 2 illustrates a state after positioning the device 1000 over the PCB 102. For example, the packaging layers 1050 are aligned relative to the PCB 102.

Stage 3 illustrates a state after attaching the device 1000 to the PCB 102. For example, after the device 1000 is placed on the PCB 102, reflow soldering is used to attach the CIs 120 to the PCB 102.

Formation of a device 1060 (e.g., a device including a mold embedded two-phase thermal management device) is complete after Stage 3 of FIG. 10. In some examples, the device 1060 corresponds to the device 100, 200, 400, 450, 500, 560, 600, 660, 700, or 760. To illustrate, in FIG. 11, an example is shown of the device 1060 corresponding to the device 100 and an example is shown of the device 1060 corresponding to the device 200. In some other examples, the device 1060 corresponds to the device 803 or 903, or a device of FIG. 15-18, 19A-D, 20A-D, 21A-D, or 22A-D.

### Exemplary Flow Diagram of a Method for Fabricating a Packaged Device/Integrated Device Including a Two-Phase Thermal Management Device

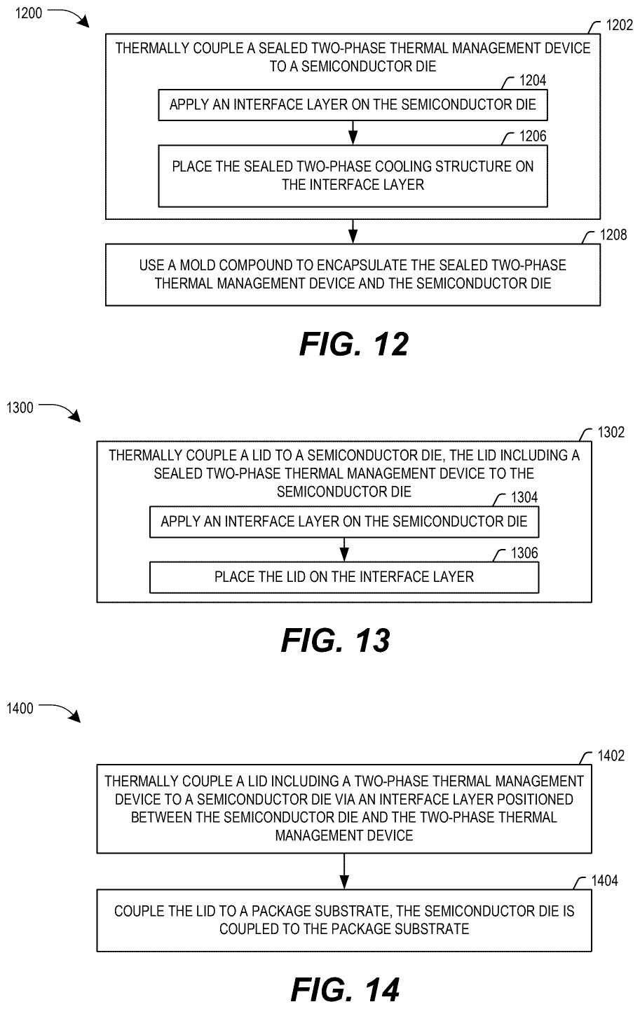

In some implementations, fabricating a device including a mold compound embedded two-phase thermal management device includes several processes. FIG. 12 illustrates an exemplary flow diagram of a method 1200 of fabricating an illustrative device that includes a mold compound embedded two-phase thermal management device. In a particular aspect, one or more operations of the method 1200 are performed by one or more processors of a fabrication system. In some implementations, operations of the method 1200 may be stored as instructions by a non-transitory computer-readable storage medium, and the instructions may be executable by at least one processor to cause the at least one processor to perform operations of the method 1200. In some implementations, the method 1200 of FIG. 12 may be used to provide or fabricate any of the device 100 of FIG. 1, the device 200 of FIG. 2, the device 400 or the device 450 of FIG. 4, the device 500 of FIG. 5A, the device 560 of FIG. 5B, the device 600 of FIG. 6A, the device 660 of FIG. 6B, the device 700 of FIG. 7A, or the device 760 of FIG. 7B.

It should be noted that the method 1200 of FIG. 12 may combine one or more processes in order to simplify and/or clarify the method for providing or fabricating an integrated circuit device. In some implementations, the order of the processes may be changed or modified.

The method 1200 includes, at block 1202, thermally coupling a sealed two-phase thermal management device to a semiconductor die. In some implementations, the method 1200 includes, at block 1204, applying an interface layer on the semiconductor die. For example, Stage 1 of FIG. 8 illustrates and describes examples of applying a layer of the mold compound 114 on the die 108 as the interface layer 122. As another example, Stage 2 of FIG. 9 illustrates and describes examples of applying an interface layer 122 on the die 108 as the interface layer 122. In some implementations, the method 1200 also includes, at block 1206, placing the sealed two-phase thermal management device on the interface layer. For example, Stage 2 of FIG. 8 illustrates and describes examples of placing the two-phase thermal management device 110 on the layer of mold compound 114. As another example, Stage 3 of FIG. 9 illustrates and describes examples of placing the two-phase thermal management device 110 on the interface layer 122.

The method 1200 includes, at block 1208, using a mold compound to encapsulate the sealed two-phase thermal management device and the semiconductor die. For example, Stage 3 of FIG. 8 illustrates and describes examples of using the mold compound 114 to encapsulate the two-phase thermal management device 110 and the die 108. As another example, Stage 4 of FIG. 9 illustrates and describes examples of using the mold compound 114 to encapsulate the two-phase thermal management device 110 and the die 108.

In some implementations, fabricating a device including a two-phase thermal management device includes several processes. FIG. 13 illustrates an exemplary flow diagram of a method 1300 of fabricating an illustrative device that includes the two-phase thermal management device. In a particular aspect, one or more operations of the method 1300 are performed by one or more processors of a fabrication system. In some implementations, operations of the method 1300 may be stored as instructions by a non-transitory computer-readable storage medium, and the instructions may be executable by at least one processor to cause the at least one processor to perform operations of the method 1300. In some implementations, the method 1300 of FIG. 13 may be used to provide or fabricate a device, such as the device 803 or 903, or a device of any of FIG. 1, 2, 6A-B, 7A-B, 15-18, 19A-D, 20A-D, 21A-D, or 22A-D.

It should be noted that the method 1300 of FIG. 13 may combine one or more processes in order to simplify and/or clarify the method for providing or fabricating an integrated circuit device. In some implementations, the order of the processes may be changed or modified.

The method 1300 includes, at block 1302, thermally coupling a lid including a sealed two-phase thermal management device to a semiconductor die. The lid includes or corresponds to the two-phase thermal management device 110 or the lid 125. The sealed two-phase thermal management device and the semiconductor die may include or correspond to the two-phase thermal management device 110 and the die 108, respectively.

In some implementations, the method 1300 includes, at block 1304, applying an interface layer on the semiconductor die. The interface layer may include or correspond to the interface layer 122. For example, Stage 1 of FIG. 8 illustrates and describes examples of applying a layer of the mold compound 114 on the die 108 as the interface layer 122. As another example, Stage 2 of FIG. 9 illustrates and describes examples of applying an interface layer 122 on the die 108 as the interface layer 122. As another example, Stage 3 of each of FIGS. 23-26 illustrate and describe applying the interface layer 122 on the die 108.

In some implementations, the method 1300 also includes, at block 1306, placing the lid on the interface layer. For example, Stage 2 of FIG. 8 illustrates and describes examples of placing the two-phase thermal management device 110 on the layer of mold compound 114. As another example, Stage 3 of FIG. 9 illustrates and describes examples of placing the two-phase thermal management device 110 on the interface layer 122. As another example, Stage 3 of FIG. 23, 25, or 26 or Stage 4 of FIG. 25 illustrate and describe placing the lid 125 on the interface layer 122.

In some implementations, fabricating a device including a two-phase thermal management device includes several processes. FIG. 14 illustrates an exemplary flow diagram of a method 1400 of fabricating an illustrative device that includes the two-phase thermal management device. In a particular aspect, one or more operations of the method 1400 are performed by one or more processors of a fabrication system. In some implementations, operations of the method 1400 may be stored as instructions by a non-transitory computer-readable storage medium, and the instructions may be executable by at least one processor to cause the at least one processor to perform operations of the method 1400. In some implementations, the method 1400 of FIG. 14 may be used to provide or fabricate a device, such as the device 803 or 903, or a device of any of FIG. 1, 2, 6A-B, 7A-B, 15-18, 19A-D, 20A-D, 21A-D, or 22A-D.

It should be noted that the method 1400 of FIG. 14 may combine one or more processes in order to simplify and/or clarify the method for providing or fabricating an integrated circuit device. In some implementations, the order of the processes may be changed or modified.

The method 1400 includes thermally coupling a lid including a two-phase thermal management device to a semiconductor die via an interface layer positioned between the semiconductor die and the two-phase thermal management device, at block 1402. The lid includes or corresponds to the two-phase thermal management device 110 or the lid 125. The two-phase thermal management device (e.g., a sealed two-phase thermal management device), the semiconductor die, and the interface layer may include or correspond to the two-phase thermal management device 110, the die 108, and the interface layer 122, respectively. For example, Stage 2 of FIG. 8 illustrates and describes examples of thermally coupling the two-phase thermal management device 110 to the die 108 via the layer of mold compound 114. As another example, Stage 3 of FIG. 9 illustrates and describes examples of thermally coupling the two-phase thermal management device 110 to the die 108 via the interface layer 122. As another example, Stage 3 of FIG. 23, 25, or 26 or Stage 4 of FIG. 25 illustrate and describe thermally coupling the two-phase thermal management device 110 to the die 108 via the interface layer 122.

The method 1400 includes coupling the lid to a package substrate, at block 1404. The package substrate may include or correspond to the substrate 104. For example, Stage 2 of FIG. 8 illustrates and describes examples of coupling the two-phase thermal management device 110 to the substrate 104. As another example, Stage 3 of FIG. 9 illustrates and describes examples of coupling the two-phase thermal management device 110 to the substrate. As another example, Stage 4 of FIGS. 23-26 illustrate and describe coupling the lid 125 (e.g., the two-phase thermal management device 110) to the substrate 104.

In some implementations, the method 1400 also includes applying the interface layer on the semiconductor die. For example, Stage 1 of FIG. 8 illustrates and describes examples of applying the interface layer 122 on the die 108. As another example, Stage 2 of FIG. 9 illustrates and describes examples of applying the interface layer 122 on the die 108. As another example, Stage 3 of FIGS. 23-26 illustrate and describe applying the interface layer 122 on the die 108.

In some implementations, the method 1400 also includes coupling a wall to the package substrate via an adhesive layer. The wall and the adhesive layer may include or correspond to the wall 126 and the adhesive layer 123, respectively. For example, Stage 2 of FIG. 23 illustrates and describes examples of coupling the wall 126 to the substrate 104 via the adhesive layer 123. In some such implementations, coupling the lid to the package substrate includes coupling the lid to the wall. For example, Stage 4 of FIG. 23 illustrates and describes examples of coupling the lid 125 to the wall 126.

In some implementations, the method 1400 also includes coupling a wall portion of the lid to the package substrate via an adhesive layer. The wall portion may include or correspond to the wall portion 136. For example, Stage 3 of FIG. 24 illustrates and describes examples of coupling the wall portion 136 of the lid 125 to the substrate 104 via the adhesive layer 123.

In some implementations, the method 1400 also includes applying a mold compound on the package substrate. The mold compound may include or correspond to the mold compound 114. For example, Stage 1 of FIG. 8 illustrates and describes applying the mold compound 114 to the substrate 104. As another example, Stage 2 of FIGS. 25 and 26 illustrate and describe applying the mold compound 114 to the substrate 104. In some such implementations, the method 1400 also may include applying the interface layer on the semiconductor die and the mold compound. For example, Stage 3 of FIGS. 25 and 26 illustrate and describe applying the interface layer 122 on the die 108 and the mold compound 114. In some such examples, after thermally coupling the lid to the semiconductor die, the interface layer is positioned between the two-phase thermal management device and the mold compound.

### Exemplary Electronic Devices

FIG. 27 illustrates various electronic devices that may include or be integrated with any of the device 100, 200, 450, 500, 560, 600, 660, 700, or 760 (that includes the mold compound embedded two-phase thermal management device), the device 803, 903, 1500, 1600, 1700, 1800, or a device of FIG. 19A-D, 20A-D, 21A-D, or 22A-D. For example, a mobile phone device 2702, a laptop computer device 2704, a fixed location terminal device 2706, a wearable device 2708, or a vehicle 2710 (e.g., an automobile or an aerial device) may include a device 2700. The device 2700 can include, for example, any of the device 100, 200, 450, 500, 560, 600, 660, 700, or 760, and/or any other integrated device that includes a mold compound embedded two-phase thermal management device described herein, the device 803, 903, 1500, 1600, 1700, 1800, or a device of FIG. 19A-D, 20A-D, 21A-D, or 22A-D. The devices 2702, 2704, 2706 and 2708 and the vehicle 2710 illustrated in FIG. 27 are merely exemplary. Other electronic devices may also feature the device 2700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

It is noted that one or more blocks (or operations) described with reference to FIGS. 12-14 may be combined with one or more blocks (or operations) described with reference to another of the figures. For example, one or more blocks (or operations) of FIG. 12 may be combined with one or more blocks (or operations) of FIG. 14. As another example, one or more blocks associated with FIG. 13 may be combined with one or more blocks (or operations) associated with FIG. 14. As another example, one or more blocks associated with FIGS. 12-14 may be combined with one or more operations associated with FIG. 1-10 or 15-26.

One or more of the components, processes, features, and/or functions illustrated in FIG. 1-27 may be rearranged and/or combined into a single component, process, feature or function or embodied in several components, processes, or functions. Additional elements, components, processes, and/or functions may also be added without departing from the disclosure. It should also be noted FIGS. 1-27 and its corresponding description in the present disclosure is not limited to dies and/or ICs. In some implementations, FIGS. 1-27 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a packaged integrated circuit device includes a semiconductor die; a sealed two-phase thermal management device thermally coupled to the semiconductor die; and a mold compound encapsulating the semiconductor die and the sealed two-phase thermal management device.

Example 2 includes the packaged integrated circuit device of Example 1, further comprising an interface layer between the sealed two-phase thermal management device and the semiconductor die.

Example 3 includes the packaged integrated circuit device of Example 1 or Example 2, wherein the interface layer includes a layer of mold compound.

Example 4 includes the packaged integrated circuit device of Example 2 or Example 3, wherein the interface layer includes a thermal interface material.

Example 5 includes the packaged integrated circuit device of any of Examples 1 to 4, wherein the sealed two-phase thermal management device extends past an edge of the semiconductor die.

Example 6 includes the packaged integrated circuit device of any of Examples 1 to 5, wherein a face of the sealed two-phase thermal management device is adjacent to and aligned with a face of the semiconductor die, and wherein the face of the sealed two-phase thermal management device is at least as large as the face of the semiconductor die.

Example 7 includes the packaged integrated circuit device of any of Examples 1 to 6, wherein the sealed two-phase thermal management device includes a vapor chamber.

Example 8 includes the packaged integrated circuit device of any of Examples 1 to 7, wherein the sealed two-phase thermal management device includes one or more heat pipes.

Example 9 includes the packaged integrated circuit device of any of Examples 1 to 8, and further includes a package substrate, the semiconductor die attached to the package substrate, wherein the semiconductor die is between the package substrate and the sealed two-phase thermal management device.

Example 10 includes the packaged integrated circuit device of any of Examples 1 to 9, and further includes a second semiconductor die, wherein the sealed two-phase thermal management device is thermally coupled to the second semiconductor die, and wherein the mold compound encapsulates the second semiconductor die.

Example 11 includes the packaged integrated circuit device of any of Examples 1 to 10, and further includes a second sealed two-phase thermal management device thermally coupled to the semiconductor die, wherein the mold compound encapsulates the second sealed two-phase thermal management device.

Example 12 includes the packaged integrated circuit device of Example 11, wherein the sealed two-phase thermal management device includes a vapor chamber and the second sealed two-phase thermal management device includes one or more heat pipes.

Example 13 includes the packaged integrated circuit device of any of Examples 1 to 12, further includes a second semiconductor die; and a second sealed two-phase thermal management device thermally coupled to the second semiconductor die, wherein the mold compound encapsulates the second semiconductor die and the second sealed two-phase thermal management device.

Example 14 includes the packaged integrated circuit device of Example 13, wherein the sealed two-phase thermal management device includes a vapor chamber and the second sealed two-phase thermal management device includes one or more heat pipes.

According to Example 15, a device includes a packaged integrated circuit device that includes a semiconductor die; a sealed two-phase thermal management device thermally coupled to the semiconductor die; and a mold compound encapsulating the semiconductor die and the sealed two-phase thermal management device; and a printed circuit board (PCB) electrically connected to the packaged integrated circuit device.

Example 16 includes the device of Example 15, wherein the packaged integrated circuit device further comprises an interface layer between the sealed two-phase thermal management device and the semiconductor die.

Example 17 includes the device of Example 15 or Example 16, wherein the interface layer includes an adhesive.

Example 18 includes the device of any of Examples 15 to 17, wherein the sealed two-phase thermal management device includes a vapor chamber.

According to Example 19, a method of fabricating a packaged integrated circuit device includes thermally coupling a sealed two-phase thermal management device to a semiconductor die; and using a mold compound to encapsulate the sealed two-phase thermal management device and the semiconductor die.

Example 20 includes the method of Example 19, wherein thermally coupling the sealed two-phase thermal management device to the semiconductor die includes: applying an interface layer on the semiconductor die; and placing the sealed two-phase thermal management device on the interface layer, wherein the mold compound encapsulates the interface layer.

According to Example 21, a packaged integrated circuit device includes a semiconductor die; a lid thermally coupled to the semiconductor die, the lid including a two-phase thermal management device; and an interface layer in contact with the semiconductor die and the lid.

Example 22 includes the packaged integrated circuit device of Example 21, where the two-phase thermal management device includes a sealed two-phase thermal management device.

Example 23 includes the packaged integrated circuit device of Example 21 or Example 22, where the interface layer includes a thermal interface material.

Example 24 includes the packaged integrated circuit device of any of Examples 21 to 23, where the two-phase thermal management device extends past an edge of the semiconductor die.

Example 25 includes the packaged integrated circuit device of any of Examples 21 to 24, where the two-phase thermal management device includes a vapor chamber.

Example 26 includes the packaged integrated circuit device of any of Examples 21 to 25, where the two-phase thermal management device includes one or more heat pipes.

Example 27 includes the packaged integrated circuit device of any of Examples 21 to 26, where the two-phase thermal management device includes a thermosyphon.

Example 28 includes the packaged integrated circuit device of any of Examples 21 to 27, where the two-phase thermal management device includes a copper structure that surrounds a cavity of the two-phase thermal management device.

Example 29 includes the packaged integrated circuit device of any of Examples 21 to 28, the packaged integrated circuit device further includes a package substrate.

Example 30 includes the packaged integrated circuit device of Example 29, where the semiconductor die is coupled to the package substrate.

Example 31 includes the packaged integrated circuit device of Example 29 or Example 30, where the semiconductor die is interposed between the package substrate and the interface layer.

Example 32 includes the packaged integrated circuit device of any of Examples 29 to 31, where a wall is coupled to the lid, and where the lid includes the two-phase thermal management device.

Example 33 includes the packaged integrated circuit device of Example 32, where the wall is coupled to the package substrate via an adhesive layer.

Example 34 includes the packaged integrated circuit device of any of Examples 29 to 31, where the lid includes a wall portion.

Example 35 includes the packaged integrated circuit device of Example 34, where the lid is coupled to the package substrate via the adhesive layer.

Example 36 includes the packaged integrated circuit device of Example 34 or Example 35 and further includes mold compound.

Example 37 includes the packaged integrated circuit device of Example 36, where the lid and the package substrate define a cavity.

Example 38 includes the packaged integrated circuit device of Example 37, where the mold compound, the semiconductor die, a die attach, and an interface layer are positioned within the cavity.

Example 39 includes the packaged integrated circuit device of any of Examples 29 to 31, further includes a mold compound coupled to the package substrate, a side surface of the semiconductor die, a side surface of a die attach positioned between the package substrate and the semiconductor die, or a combination thereof.

Example 40 includes the packaged integrated circuit device of Example 39, where the mold compound is interposed between an interface layer and the package substrate.

Example 41 includes the packaged integrated circuit device of any of Example 39 or Example 40, where the interface layer is interposed between the mold compound and the lid.

Example 42 includes the packaged integrated circuit device of any of Examples 39 to 41, where the mold compound defines a portion of an outer surface of the packaged integrated circuit device.

Example 43 includes the packaged integrated circuit device of any of Examples 29 to 31, the packaged integrated circuit device further includes a second semiconductor die coupled to the package substrate.

Example 44 includes the packaged integrated circuit device of Example 43, where the lid is thermally coupled to the second semiconductor die.

Example 45 includes the packaged integrated circuit device of Example 43 or Example 44, where the second semiconductor die is positioned between the package substrate and the lid.

According to Example 46, a device includes a packaged integrated circuit device, the packaged integrated circuit device including a semiconductor die; a lid thermally coupled to the semiconductor die, the lid including a two-phase thermal management device; and an interface layer between the semiconductor die and the two-phase thermal management device.

Example 47 includes the device of Example 46, the device further includes a printed circuit board (PCB) electrically connected to the packaged integrated circuit device.

Example 48 includes the device of Example 46 or Example 47, where the lid defines a portion of an outer surface of the packaged integrated circuit device.

According to Example 49, a device includes a packaged integrated circuit device of any of Examples 21 to 45.

Example 50 includes the device of Example 49, the device further includes a printed circuit board (PCB) electrically connected to the packaged integrated circuit device.

Example 51 includes the device of Example 49 or Example 50, where the lid defines a portion of an outer surface of the packaged integrated circuit device.

According to Example 52, a method of fabricating a packaged integrated circuit device, the method includes thermally coupling a lid including a two-phase thermal management device to a semiconductor die via an interface layer positioned between the semiconductor die and the two-phase thermal management device; and coupling the lid to a package substrate, where the semiconductor die is coupled to the package substrate.

Example 53 includes the method of Example 52, the method further includes coupling a wall to the package substrate via an adhesive layer.

Example 54 includes the method of Example 53, where coupling the lid to the package substrate includes coupling the lid to the wall.

Example 55 includes the method of Example 52 or Example 53, where the lid includes a wall portion.

Example 56 includes the method of Example 52, where coupling the lid to the package substrate includes coupling the wall portion of the lid to the package substrate via an adhesive layer.

Example 57 includes the method of any of Examples 52 to 56, the method further includes applying a mold compound on the package substrate.

Example 58 includes the method of Example 57, the method further includes applying the interface layer on the semiconductor die and the mold compound.

Example 59 includes the method of Example 57 or Example 58, where, after thermally coupling the lid to the semiconductor die, the interface layer is positioned between the two-phase thermal management device and the mold compound.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A packaged integrated circuit device comprising:
a semiconductor die;
a lid thermally coupled to the semiconductor die, the lid including a two-phase thermal management device; and
an interface layer in contact with the semiconductor die and the lid.

2. The packaged integrated circuit device of claim 1, wherein:
the two-phase thermal management device includes a sealed two-phase thermal management device; and
the interface layer includes a thermal interface material.

3. The packaged integrated circuit device of claim 1, wherein the two-phase thermal management device extends past an edge of the semiconductor die.

4. The packaged integrated circuit device of claim 1, wherein the two-phase thermal management device includes a vapor chamber.

5. The packaged integrated circuit device of claim 1, wherein the two-phase thermal management device includes one or more heat pipes.

6. The packaged integrated circuit device of claim 1, wherein the two-phase thermal management device includes a thermosyphon.

7. The packaged integrated circuit device of claim 1, wherein the two-phase thermal management device includes a copper structure that surrounds a cavity of the two-phase thermal management device.

8. The packaged integrated circuit device of claim 1, further comprising:
a package substrate, wherein the semiconductor die is coupled to the package substrate; and
wherein the semiconductor die is interposed between the package substrate and the interface layer.

9. The packaged integrated circuit device of claim 8, further comprising:
a wall coupled to the lid, and where the lid includes the two-phase thermal management device; and
the wall is coupled to the package substrate via an adhesive layer.

10. The packaged integrated circuit device of claim 9, wherein:
the lid includes a wall portion; and
the lid is coupled to the package substrate via the adhesive layer.

11. The packaged integrated circuit device of claim 10, further comprising:
mold compound; and
wherein:
the lid and the package substrate define a cavity; and
the mold compound, the semiconductor die, a die attach, and the interface layer are positioned within the cavity.

12. The packaged integrated circuit device of claim 8, further comprising:
a mold compound coupled to the package substrate, a side surface of the semiconductor die, a side surface of a die attach positioned between the package substrate and the semiconductor die, or a combination thereof.

13. The packaged integrated circuit device of claim 12, wherein:
the mold compound is interposed between an interface layer and the package substrate;
the interface layer is interposed between the mold compound and the lid; or
the mold compound defines a portion of an outer surface of the packaged integrated circuit device.

14. The packaged integrated circuit device of claim 8, further comprising:
a second semiconductor die coupled to the package substrate; and
wherein:
the lid is thermally coupled to the second semiconductor die, and
the second semiconductor die is positioned between the package substrate and the lid.

15. A device comprising:
a packaged integrated circuit device including:
a semiconductor die;
a lid thermally coupled to the semiconductor die, the lid including a two-phase thermal management device; and
an interface layer between the semiconductor die and the two-phase thermal management device.

16. The device of claim 15, further comprising:
a printed circuit board (PCB) electrically connected to the packaged integrated circuit device; and
wherein the lid defines a portion of an outer surface of the packaged integrated circuit device.

17. A method of fabricating a packaged integrated circuit device, the method comprising:
thermally coupling a lid including a two-phase thermal management device to a semiconductor die via an interface layer positioned between the semiconductor die and the two-phase thermal management device; and
coupling the lid to a package substrate, wherein the semiconductor die is coupled to the package substrate.

18. The method of claim 17, further comprising:
coupling a wall to the package substrate via an adhesive layer; and
wherein coupling the lid to the package substrate includes coupling the lid to the wall.

19. The method of claim 17, wherein:
the lid includes a wall portion; and
wherein coupling the lid to the package substrate includes coupling the wall portion of the lid to the package substrate via an adhesive layer.

20. The method of claim 17, further comprising:
applying a mold compound on the package substrate; and
applying the interface layer on the semiconductor die and the mold compound; and
wherein, after thermally coupling the lid to the semiconductor die, the interface layer is positioned between the two-phase thermal management device and the mold compound.
